(19) United States
(12) Patent Application Publication
(10) Pub. No.: US 2021/0210707 A1
(43) Pub. Date: Jul. 8, 2021

(54) STACKED PEROVSKITE LIGHT EMITTING DEVICE

(71) Applicant: PEROLED LIMITED, Sedgefield (GB)

(72) Inventor: Peter LEVERMORE, Sedgefield (GB)

(21) Appl. No.: 17/056,857

(22) PCT Filed: May 23, 2019
(86) PCT No.: PCT/GB2019/051425

§ 371 Date: Nov. 19, 2020

(30) Foreign Application Priority Data
May 23, 2018 (GB) 1808439.2

(51) Int. Cl. H01L 51/50; H01L 51/52

(52) U.S. Cl. CPC H01L 51/502; H01L 51/5036; H01L 51/5265; H01L 51/5278

(57) ABSTRACT

A light emitting device is provided. The device comprises a first electrode, a second electrode, at least two emissive units and at least one charge generation layer. The at least two emissive units and at least one charge generation layer are disposed between the first electrode and the second electrode. A first emissive unit of the at least two emissive units is disposed over the first electrode. A first charge generation layer of the at least one charge generation layer is disposed over the first emissive unit. A second emissive unit of the at least two emissive units is disposed over the first charge generation layer. The second electrode is disposed over the second emissive unit. At least one emissive unit of the at least two emissive units comprises a perovskite light emitting material. The device comprises at least one further emissive unit of the at least two emissive units, wherein the at least one further emissive unit comprises a perovskite light emitting material, an organic light emitting material or a quantum dot light emitting material.

### TECHNICAL FIELD

The present invention relates to light emitting devices, and in particular to stacked light emitting devices that comprise one or more perovskite light emitting materials and two or more emissive units for application in devices, such as displays, light panels and other devices including the same.

### BACKGROUND

Perovskite materials are becoming increasingly attractive for application in optoelectronic devices. Many of the perovskite materials used to make such devices are earth-abundant and relatively inexpensive, so perovskite optoelectronic devices have the potential for cost advantages over alternative organic and inorganic devices. Additionally, inherent properties or perovskite materials, such as an optical band gap that is readily tunable across the visible, ultra-violet and infra-red, render them well suited for optoelectronics applications, such as perovskite light emitting diodes (PeLEDs), perovskite solar cells and photodetectors, perovskite lasers, perovskite transistors, perovskite visible light communication (VLC) devices and others. PeLEDs comprising perovskite light emitting material may have performance advantages over conventional organic light emitting diodes (OLEDs) and quantum dot light emitting diodes (QLEDs), respectively comprising organic light emitting material and quantum dot light emitting material. For example, strong electroluminescent properties, including unrivalled high colour purity enabling displays with wider colour gamut, excellent charge transport properties and low non-radiative rates.

PeLEDs make use of thin perovskite films that emit light when voltage is applied. PeLEDs are becoming an increasingly attractive technology for use in applications such as displays, lighting and signage. As an overview, several PeLED materials and configurations are described in Adjokatse et al., which is included herein by reference in its entirety.

One potential application for perovskite light-emitting materials is a display. Industry standards for a full-colour display require for sub-pixels to be engineered to emit specific colours, referred to as “saturated” colours. These standards call for saturated red, green and blue sub-pixels, where colour may be measured using CIE 1931 (x, y) chromaticity coordinates, which are well known in the art. One example of a perovskite material that emits red light is methylammonium lead iodide (CH₃NH₃PbI₃). One example of a perovskite material that emits green light is formamidinium lead bromide (CH(NH₂)₂PbBr₃). One example of a perovskite material that emits blue light is methylammonium lead chloride (CH₃NH₃PbCl₃). In a display, performance advantages, such as increased colour gamut, may be achieved where PeLEDs are used in place of or in combination with OLEDs and/or QLEDs. In the present invention, performance advantages are demonstrated by including one or more perovskite light emitting materials in stacked light emitting devices with multiple emissive units.

As used herein, the term “perovskite” includes any perovskite material that may be used in an optoelectronic device. Any material that may adopt a three-dimensional (3D) structure of ABX₃, where A and B are cations and X is an anion, may be considered a perovskite material. FIG. 3 depicts an example of a perovskite material with a 3D structure of ABX₃. The A cations may be larger than the B cations. The B cations may be in 6-fold coordination with surrounding X anions. The A anions may be in 12-fold coordination with surrounding X anions.

There are many classes of perovskite material. One class of perovskite material that has shown particular promise for optoelectronic devices is the metal halide perovskite material class. For metal halide perovskite material, the A component may be a monovalent organic cation, such as methylammonium (CH₃NH₃⁺) or formamidinium (CH(NH₂)₂⁺), an inorganic atomic cation, such as caesium (Cs⁺), or a combination thereof, the B component may be a divalent metal cation, such as lead (Pb⁺), tin (Sn⁺), copper (Cu⁺), europium (Eu⁺) or a combination thereof, and the X component may be a halide anion, such as I⁻, Br⁻, Cl⁻, or a combination thereof. Where the A component is an organic cation, the perovskite material may be defined as an organic metal halide perovskite material. CH₃NH₃PbBr₃ and CH(NH₂)₂PbI₃ are non-limiting examples of metal halide perovskite materials with a 3D structure. Where the A component is an inorganic cation, the perovskite material may be defined as an inorganic metal halide perovskite material. CsPbI₃, CsPbCl₃ and CsPbBr₃ are non-limiting examples of inorganic metal halide perovskite materials.

As used herein, the term “perovskite” further includes any material that may adopt a layered structure of L₂(ABX₃)ₙ₋₁BX₄ (which may also be written as L₂Aₙ₋₁BₙX₃ₙ₊₁), where L, A and B are cations, X is an anion, and n is the number of BX₄ monolayers disposed between two layers of cation L. FIG. 4 depicts examples of perovskite materials with a layered structure of L₂(ABX₃)ₙ₋₁BX₄ having different values for n. For metal halide perovskite material, the A component may be a monovalent organic cation, such as methylammonium (CH₃NH₃⁺) or formamidinium (CH(NH₂)₂⁺), an atomic cation, such as caesium (Cs⁺), or a combination thereof, the L component may be an organic cation such as 2-phenylethylammonium (C₆H₅C₂H₄NH₃⁺) or 1-napthylmethylammonium (C₁₀H₇CH₂NH₃⁺), the B component may be a divalent metal cation, such as lead (Pb⁺), tin (Sn⁺), copper (Cu⁺), europium (Eu⁺) or a combination thereof, and the X component may be a halide anion, such as I⁻, Br⁻, Cl⁻, or a combination thereof. (C₆H₅C₂H₄NH₃)₂(CH(NH₂)₂PbBr₃)ₙ₋₁PbBr₄ and (C₁₀H₂CH₂NH₃)₂(CH₃NH₃PbI₂Br)ₙ₋₁PbI₃Br are non-limiting examples of metal halide perovskite material with a layered structure. Where the number of layers n is large, for example n greater than approximately 10, perovskite material with a layered structure of L₂(ABX₃)ₙ₋₁BX₄ adopts a structure that is approximately equivalent to perovskite material with a 3D structure of ABX₃. As used herein, and as would generally be understood by one skilled in the art, perovskite material having a large number of layers may be referred to as a 3D perovskite material, even though it is recognized that such perovskite material has reduced dimensionality from n=∞. Where the number of layers n=1, perovskite material with a layered structure of L₂(ABX₃)ₙ₋₁BX₄ adopts a two-dimensional (2D) structure of L₂BX₄. Perovskite material having a single layer may be referred to as a 2D perovskite material. Where n is small, for example n in the range of approximately 2-10, perovskite material with a layered structure of L₂(ABX₃)ₙ₋₁BX₄ adopts a quasi-two-dimensional (Quasi-2D) structure. Perovskite material having a small number of layers may be referred to as a Quasi-2D perovskite material. Owing to quantum confinement effects, the energy band gap is lowest for layered perovskite material structures where n is highest.

Perovskite material may have any number of layers. Perovskites may comprise 2D perovskite material, Quasi-2D perovskite material, 3D perovskite material or a combination thereof. For example, perovskites may comprise an ensemble of layered perovskite materials having different numbers of layers. For example, perovskites may comprise an ensemble of Quasi-2D perovskite materials having different numbers of layers.

As used herein, the term “perovskite” further includes films of perovskite material. Films of perovskite material may be crystalline, polycrystalline or a combination thereof, with any number of layers and any range of grain or crystal size.

As used herein, the term “perovskite” further includes nanocrystals of perovskite material that have structure equivalent to or resembling the 3D perovskite structure of ABX₃ or the more general layered perovskite structure of L₂(ABX₃)ₙ₋₁BX₄. Nanocrystals of perovskite material may include perovskite nanoparticles, perovskite nanowires, perovskite nanoplatelets, or a combination thereof. Nanocrystals of perovskite material may be of any shape or size, with any number of layers and any range of grain or crystal sizes. FIG. 5 depicts an example of nanocrystal of perovskite material with a layered structure that resembles L₂(ABX₃)ₙ₋₁BX₄, where n=5 and L cations are arranged at the surface of the perovskite nanocrystal. The term “resembles” is used because for a nanocrystal of perovskite material, the distribution of L cations may differ from that of perovskite material with a formal layered structure of L₂(ABX₃)ₙ₋₁BX₄. For example, in a nanocrystal of perovskite material, there may be a greater proportion of L cations arranged along the sides of the nanocrystal.

Several types of perovskite material may be stimulated to emit light in response to optical or electrical excitation. That is to say that perovskite light emitting material may be photoluminescent or electroluminescent. As used herein, the term “perovskite light emitting material” refers exclusively to electroluminescent perovskite light emitting material that is emissive through electrical excitation. Wherever “perovskite light emitting material” is referred to in the text, it should be understood that reference is being made to electroluminescent perovskite light emitting material. This nomenclature may differ slightly from that used by other sources.

In general, PeLED devices may be photoluminescent or electroluminescent. As used herein, the term “PeLED” refers exclusively to electroluminescent devices that comprise electroluminescent perovskite light emitting material. The term “PeLED” may be used to describe single emissive unit electroluminescent devices that comprise electroluminescent perovskite light emitting material. The term “PeLED” may also be used to describe one or more emissive units of stacked electroluminescent devices that comprise electroluminescent perovskite light emitting material. This nomenclature may differ slightly from that used by other sources.

As used herein, the term “organic” includes polymeric materials as well as small molecule organic materials that may be used to fabricate optoelectronic devices, such as OLEDs. As used herein, the term small molecule refers to any organic material that is not a polymer, and small molecules may actually be quite large. Small molecules may include repeat units in some circumstances. For example, using a long chain alkyl group as a substituent does not remove a molecule from the small molecule class. Small molecules may also be incorporated into polymers, for example as a pendant group on a polymer backbone or as part of the backbone. Small molecules may also serve as the core moiety of a dendrimer, which consists of a series of chemical shells built on the core moiety. The core moiety of a dendrimer may be a small molecule. A dendrimer may be a small molecule and it is believed that all dendrimers currently used in the field of OLEDs are small molecules.

As used herein the term “organic light emitting material” includes fluorescent and phosphorescent organic light emitting materials, as well as organic materials that emit light through mechanisms such as triplet-triplet annihilation (TTA) or thermally activated delayed fluorescence (TADF). One example of organic light emitting material that emits red light is Bis(2-(3,5-dimethylphenyl)quinoline-C2,N′) (acetylacetonato) iridium(III) Ir(dmpq)₂(acac). One example of organic light emitting material that emits green light is tris(2-phenylpyridine)iridium (Ir(ppy)₃). One example of organic light emitting material that emits blue light is Bis[2-(4,6-difluorophenyl)pyridinato-C2,N](picolinato)iridium(III) (Flrpic).

In general, OLED devices may be photoluminescent or electroluminescent. As used herein, the term “OLED” refers exclusively to electroluminescent devices that comprise electroluminescent organic light emitting material. The term “OLED” may be used to describe single emissive unit electroluminescent devices that comprise electroluminescent organic light emitting material. The term “OLED” may also be used to describe one or more emissive units of stacked electroluminescent devices that comprise electroluminescent organic light emitting material. This nomenclature may differ slightly from that used by other sources.

As used herein, the term “quantum dot” includes quantum dot material, quantum rod material and other luminescent nanocrystal material, with the exception of “perovskite” material, which is defined separately herein. Quantum dots may generally be considered as semiconductor nanoparticles that exhibit properties that are intermediate between bulk semiconductors and discrete molecules. Quantum dots may comprise III-V semiconductor material, such as gallium nitride (GaN), gallium phosphide (GaP), gallium arsenide (GaAs), indium phosphide (InP) and indium arsenide (InAs), or II-VI semiconductor material, such as zinc oxide (ZnO), zinc sulfide (ZnS), cadmium sulfide (CdS), cadmium selenide (CdSe) and cadmium telluride (CdTe), or combinations thereof. In general, as a result of quantum confinement effects, optoelectronic properties of quantum dots may change as a function of size or shape of the quantum dot.

Several types of quantum dot may be stimulated to emit light in response to optical or electrical excitation. That is to say that quantum dot light emitting material may be photoluminescent or electroluminescent. As used herein, the term “quantum dot light emitting material” refers exclusively to electroluminescent quantum dot light emitting material that is emissive through electrical excitation. Wherever “quantum dot light emitting material” is referred to in the text, it should be understood that reference is being made to electroluminescent quantum dot light emitting material. This nomenclature may differ slightly from that used by other sources.

As used herein, the term “quantum dot” does not include “perovskite” material. Several types of perovskite material, such as perovskite nanocrystals, 2D perovskite materials and Quasi-2D perovskite materials, are semiconducting materials that exhibit properties intermediate between bulk semiconductors and discrete molecules, where in a similar manner to quantum dots, quantum confinement may affect optoelectronic properties. However, as used herein, such materials are referred to as “perovskite” materials and not “quantum dot” materials. A first reason for this nomenclature is that perovskite materials and quantum dot materials, as defined herein, generally comprise different crystal structures. A second reason for this nomenclature is that perovskite materials and quantum dot materials, as defined herein, generally comprise different material types within their structures. A third reason for this nomenclature is that emission from perovskite material is generally independent of the structural size of the perovskite material, whereas emission from quantum dot material is generally dependent on the structural size (e.g. core and shell) of the quantum dot material. This nomenclature may differ slightly from that used by other sources.

In general, quantum dot light emitting materials comprise a core. Optionally, the core may be surrounded by one or more shells. Optionally, the core and one or more shells may be surrounded by a passivation structure. Optionally, the passivation structure may comprise ligands bonded to the one or more shells. The size of the of the core and shell(s) may influence the optoelectronic properties of quantum dot light emitting material. Generally, as the size of the core and shell(s) is reduced, quantum confinement effects become stronger, and electroluminescent emission may be stimulated at shorter wavelength. For display applications, the diameter of the core and shell(s) structure is typically in the range of 1-10 nm. Quantum dots that emit blue light are typically the smallest, with core-shell(s) diameter in the approximate range of 1-2.5 nm. Quantum dots that emit green light are typically slightly larger, with core-shell(s) diameter in the approximate range of 2.5-4 nm. Quantum dots that emit red light are typically larger, with core-shell(s) diameter in the approximate range of 5-7 nm. It should be understood that these ranges are provided by way of example and to aid understanding, and are not intended to be limiting.

Examples of quantum dot light emitting materials include materials comprising a core of CdSe. CdSe has a bulk bandgap of 1.73 eV, corresponding to emission at 716 nm. However, the emission spectrum of CdSe may be adjusted across the visible spectrum by tailoring the size of the CdSe quantum dot. Quantum dot light emitting materials comprising a CdSe core may further comprise one or more shells, comprising CdS, ZnS or combinations thereof. Quantum dot light emitting materials comprising CdSe may further comprise a passivation structure, which may include ligands bonded to the shell(s). Quantum dot light emitting materials comprising CdSe/CdS or CdSe/ZnS core-shell structures may be tuned to emit red, green or blue light for application in displays and/or light panels.

Examples of quantum dot light emitting materials further include materials comprising a core of InP. InP has a bulk bandgap of 1.35 eV, corresponding to emission at 918 nm. However, the emission spectrum of InP may be adjusted across the visible spectrum by tailoring the size of the InP quantum dot. Quantum dot light emitting materials comprising a InP core may further comprise one or more shells of CdS, ZnS or combinations thereof. Quantum dot light emitting materials comprising InP may further comprise a passivation structure, which may include ligands bonded to the shell(s). Quantum dot light emitting materials comprising InP/CdS or InP/ZnS core-shell structures may be tuned to emit red, green or blue light for application in displays and/or light panels.

In general, QLED devices may be photoluminescent or electroluminescent. As used herein, the term “QLED” refers exclusively to electroluminescent devices that comprise electroluminescent quantum dot light emitting material. The term “QLED” may be used to describe single emissive unit electroluminescent devices that comprise electroluminescent quantum dot light emitting material. The term “QLED” may also be used to describe one or more emissive units of stacked electroluminescent devices that comprise electroluminescent quantum dot light emitting material. This nomenclature may differ slightly from that used by other sources.

As used herein, “top” means furthest away from the substrate, while “bottom” means closest to the substrate. Where a first layer is described as “disposed over” a second layer, the first layer is disposed further away from the substrate. There may be other layers between the first and second layer, unless it is specified that the first layer is “in contact with” the second layer.

As used herein, “solution processible” means capable of being dissolved, dispersed or transported in and/or deposited from a liquid medium, either in solution or suspension form.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) and electron affinities (EA) are measured as negative energies relative to a vacuum level, a higher HOMO energy level corresponds to an IP that is less negative. Similarly, a higher LUMO energy level corresponds to an EA that is less negative. On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. The definitions of HOMO and LUMO energy levels therefore follow a different convention than work functions.

As used herein, the term “optically coupled” refers to one or more elements of a device or structure that are arranged such that light may impart between the one or more elements. The one or more elements may be in contact or may be separated by a gap or any connection, coupling, link or the like that allows for imparting of light between the one or more elements. For example, one or more stacked light emitting devices may be optically coupled to one or more colour altering layers through a transparent or semi-transparent substrate.

As used herein, and as would be generally understood by one skilled in the art, a light emitting device, such as a PeLED, OLED or QLED may be referred to as a “stacked” light emitting device if two or more emissive units are separated by one or more charge generation layers within the layer structure of the light emitting device. In some sources, a stacked light emitting device may be referred to as a tandem light emitting device. It should be understood that the terms “stacked” and “tandem” may be used interchangeably, and as used herein, a tandem light emitting device is also considered to be a stacked light emitting device. This nomenclature may differ slightly from that used by other sources.

It should be understood that PeLEDs, OLEDs and QLEDs are light emitting diodes, and as used herein, a light emitting diode is considered to be a light emitting device that allows substantial current flow in only one direction. PeLEDs, OLEDs and QLEDs are therefore considered to be driven by direct current (DC) and not alternating current (AC). As used herein, the terms “PeLED”, “OLED” and “QLED” may be used to describe single emissive unit electroluminescent devices that respectively comprise electroluminescent perovskite, organic or quantum dot light emitting materials. The terms “PeLED”, “OLED” and “QLED” may also be used to describe one or more emissive units of stacked electroluminescent devices that respectively comprise electroluminescent perovskite, organic or quantum dot light emitting materials. It should therefore be understood that electroluminescent light emitting devices disclosed herein allow substantial current flow in only one direction through their respective PeLED, OLED and/or QLED emissive units. The electroluminescent light emitting devices disclosed herein are therefore considered to be driven by direct current (DC) and not alternating current (AC). This nomenclature may differ slightly from that used by other sources.

### SUMMARY

A light emitting device is provided. In one embodiment, the light emitting device comprises a first electrode, a second electrode, at least two emissive units and at least one charge generation layer. The at least two emissive units and at least one charge generation layer are disposed between the first electrode and the second electrode. A first emissive unit of the at least two emissive units is disposed over the first electrode. A first charge generation layer of the at least one charge generation layer is disposed over the first emissive unit. A second emissive unit of the at least two emissive units is disposed over the first charge generation layer. The second electrode is disposed over the second emissive unit. At least one emissive unit of the at least two emissive units comprises a perovskite light emitting material. The device comprises at least one further emissive unit of the at least two emissive units, wherein the at least one further emissive unit of the at least two emissive units comprises a perovskite light emitting material, an organic light emitting material or a quantum dot light emitting material.

In one embodiment, the first emissive unit comprises a perovskite light emitting material, and the second emissive unit comprises a perovskite light emitting material, an organic light emitting material or a quantum dot light emitting material. In one embodiment, the first emissive unit comprises a perovskite light emitting material, an organic light emitting material or a quantum dot light emitting material, and the second emissive unit comprises a perovskite light emitting material.

In one embodiment, the at least one further emissive unit of the at least two emissive units comprises a perovskite light emitting material or an organic light emitting material. In one embodiment, the first emissive unit comprises a perovskite light emitting material, and the second emissive unit comprises a perovskite light emitting material. In one embodiment, the at least one further emissive unit of the at least two emissive units comprises an organic light emitting material. In one embodiment, the first emissive unit comprises a perovskite light emitting material, and the second emissive unit comprises an organic light emitting material. In one embodiment, the first emissive unit comprises an organic light emitting material, and the second emissive unit comprises a perovskite light emitting material.

In one embodiment, the at least one further emissive unit of the at least two emissive units comprises a perovskite light emitting material or a quantum dot light emitting material. In one embodiment, the first emissive unit comprises a perovskite light emitting material, and the second emissive unit comprises a perovskite light emitting material. In one embodiment, the at least one further emissive unit of the at least two emissive units comprises a quantum dot light emitting material. In one embodiment, the first emissive unit comprises a perovskite light emitting material, and the second emissive unit comprises a quantum dot light emitting material. In one embodiment, the first emissive unit comprises a quantum dot light emitting material, and the second emissive unit comprises a perovskite light emitting material.

In one embodiment, each emissive unit comprises one, and not more than one, emissive layer. In one embodiment, each emissive unit comprises one, and not more than one, emissive material. In one embodiment, the light emitting device includes a microcavity structure.

In one embodiment, the light emitting device emits red light. In one embodiment, the light emitting device emits red light with CIE 1931×coordinate greater than or equal to 0.680. In one embodiment, the light emitting device emits red light with CIE 1931×coordinate greater than or equal to 0.708. In one embodiment, the light emitting device emits green light. In one embodiment, the light emitting device emits green light with CIE 1931 y coordinate greater than or equal to 0.690. In one embodiment, the light emitting device emits green light with CIE 1931 y coordinate greater than or equal to 0.797. In one embodiment, the light emitting device emits blue light. In one embodiment, the light emitting device emits blue light with CIE y coordinate less than or equal to 0.060. In one embodiment, the light emitting device emits blue light with CIE y coordinate less than or equal to 0.046. In one embodiment, the light emitting device emits white light.

In one embodiment, one or more of the emissive units of the device may comprise organic metal halide light-emitting perovskite material. In one embodiment, one or more of the emissive units of the device may comprise inorganic metal halide light-emitting perovskite material.

In one embodiment, the first charge generation layer is directly connected to an external electrical source. In one embodiment, the first charge generation layer is independently addressable. In one embodiment, the first charge generation layer is not directly connected to an external electrical source. In one embodiment, the first charge generation layer is not independently addressable. In one embodiment, the first emissive unit and the second emissive unit are electrically connected in series. In one embodiment, direct current passes through the first emissive unit and the second emissive unit.

In one embodiment, the light emitting device may be included in a sub-pixel of a display. In one embodiment, the light emitting device may be included in a light panel.

In one embodiment, the light emitting device comprises a first electrode, a second electrode, at least three emissive units and at least two charge generation layers. The at least three emissive units and at least two charge generation layers are disposed between the first electrode and the second electrode. A first emissive unit of the at least three emissive units is disposed over the first electrode. A first charge generation layer of the at least two charge generation layers is disposed over the first emissive unit. A second emissive unit of the at least three emissive units is disposed over the first charge generation layer. A second charge generation layer of the at least two charge generation layers is disposed over the second emissive unit. A third emissive unit of the at least three emissive units is disposed over the second charge generation layer. The second electrode is disposed over the third emissive unit. At least one emissive unit of the at least three emissive units comprises a perovskite light emitting material. The device comprises at least two further emissive units of the at least three emissive units, wherein each of the at least two emissive units comprises a perovskite light emitting material, an organic light emitting material or a quantum dot light emitting material.

In one embodiment, the at least two further emissive units of the at least three emissive units each comprise a perovskite light emitting material or an organic light emitting material. In one embodiment, the first emissive unit comprises a perovskite light emitting material, the second emissive unit comprises a perovskite light emitting material, and the third emissive unit comprises a perovskite light emitting material. In one embodiment, the at least two further emissive units of the at least three emissive units each comprise a perovskite light emitting material or an organic light emitting material, wherein at least one emissive unit of the at least two further emissive units comprises an organic light emitting material.

In one embodiment, the at least two further emissive units of the at least three emissive units each comprise a perovskite light emitting material or a quantum dot light emitting material. In one embodiment, the first emissive unit comprises a perovskite light emitting material, the second emissive unit comprises a perovskite light emitting material, and the third emissive unit comprises a perovskite light emitting material. In one embodiment, the at least two further emissive units of the at least three emissive units each comprise a perovskite light emitting material or a quantum dot light emitting material, wherein at least one emissive unit of the at least two further emissive units comprises a quantum dot light emitting material.

In one embodiment, at least one emissive unit of the at least two further emissive units comprises an organic light emitting material, and at least one emissive unit of the at least two further emissive units comprises a quantum dot light emitting material.

### DESCRIPTION OF THE DRAWINGS

The summary above, as well as the following detailed description of illustrative embodiments, is better understood when read in conjunction with the appended drawings. For the purpose of illustrating the present disclosure, exemplary constructions of the disclosure are shown in the drawings. However, the present disclosure is not limited to specific methods and instrumentalities disclosed herein. Moreover, those in the art will understand that the drawings are not to scale.

In the accompanying drawings, an underlined number is employed to represent an item over which the underlined number is positioned or an item to which the underlined number is adjacent. A non-underlined number relates to an item identified by a line linking the non-underlined number to the item. When a number is non-underlined and accompanied by an associated arrow, the non-underlined number is used to identify a general item at which the arrow is pointing. Embodiments of the present disclosure will now be described, by way of example only, with reference to the following:

FIG. 1 depicts a light emitting device.

FIG. 2 depicts an inverted light emitting device.

FIG. 3 depicts 3D perovskite light emitting material with structure ABX₃.

FIG. 4 depicts layered perovskite light emitting material with structure L₂(ABX₃)ₙ₋₁BX₄, where n=1, 3, 5, 10 and ∞.

FIG. 5 depicts an example of a nanocrystal of perovskite materials with a layered structure that resembles L₂(ABX₃)ₙ₋₁BX₄, where n=5.

FIG. 6 depicts a stacked light emitting device having two emissive units.

FIG. 7 depicts a stacked light emitting device having three emissive units.

FIG. 8 depicts a layer structure for a stacked light emitting device having two emissive units.

FIG. 9 depicts a layer structure for a stacked light emitting device having three emissive units.

FIG. 10 depicts a rendition of the CIE 1931 (x, y) colour space chromaticity diagram.

FIG. 11 depicts a rendition of the CIE 1931(x, y) colour space chromaticity diagram that also shows colour gamut for (a) DCI-P3 and (b) Rec. 2020 colour spaces

FIG. 12 depicts a rendition of the CIE 1931 (x, y) colour space chromaticity diagram that also shows colour gamut for (a) DCI-P3 and (b) Rec. 2020 colour spaces with colour coordinates for exemplary red, green and blue PeLED, OLED and QLED devices.

FIG. 13 depicts a rendition of the CIE 1931 (x, y) color space chromaticity diagram that also shows the Planckian Locus.

FIG. 14 depicts exemplary electroluminescence emission spectra for red, green and blue PeLEDs, OLEDs and QLEDs.

FIG. 15 depicts various configurations of emissive units for a stacked light emitting device having two emissive units.

FIG. 16 depicts various configurations of emissive units for a stacked light emitting device having three emissive units.

FIG. 17 depicts further various configurations of emissive units for a stacked light emitting device having three emissive units.

### DESCRIPTION OF EMBODIMENTS

General device architectures and operating principles for PeLEDs are substantially similar to those for OLEDs and QLEDs. Each of these light emitting devices comprises at least one emissive layer disposed between and electrically connected to an anode and a cathode. For a PeLED, the emissive layer comprises perovskite light emitting material. For an OLED, the emissive layer comprises organic light emitting material. For a QLED, the emissive layer comprises quantum dot light emitting material. For each of these light emitting devices, when a current is applied, the anode injects holes and the cathode injects electrons into the emissive layer(s). The injected holes and electrons each migrate towards the oppositely charged electrode. When an electron and a hole localize, an exciton, which is a localized electron-hole pair having an excited energy state, may be formed. Light is emitted if the exciton relaxes via a photo-emissive mechanism. Non-radiative mechanisms, such as thermal radiation and/or Auger recombination may also occur, but are generally considered undesirable. Substantial similarity between device architectures and working principles required for PeLEDs, OLEDs and QLEDs, facilitates the combination of perovskite light emitting material, organic light emitting material and quantum dot light emitting material in a single device, such as a stacked light emitting device.

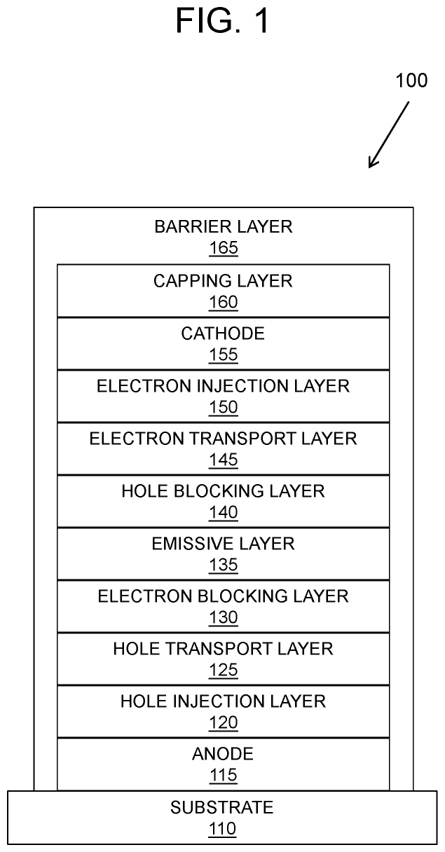

FIG. 1 shows a light emitting device 100 with a single emissive unit. The light emitting device 100 may be a PeLED, OLED or QLED. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a cathode 155, a capping layer 160, and a barrier layer 165. Device 100 may be fabricated by depositing the layers described in order. As the device 100 has anode 115 disposed under cathode 155, device 100 may be referred to as a “standard” device architecture. For a PeLED, the emissive layer comprises perovskite light emitting material. For an OLED, the emissive layer comprises organic light emitting material. For a QLED, the emissive layer comprises quantum dot light emitting material.

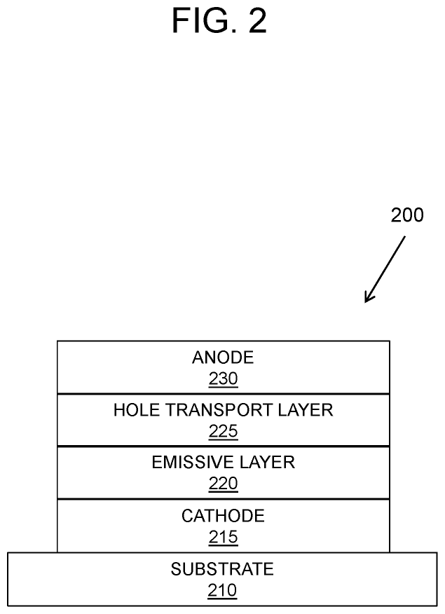

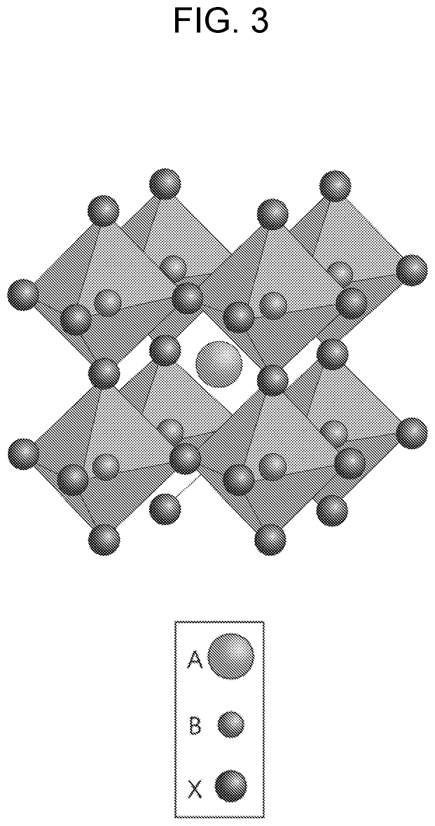

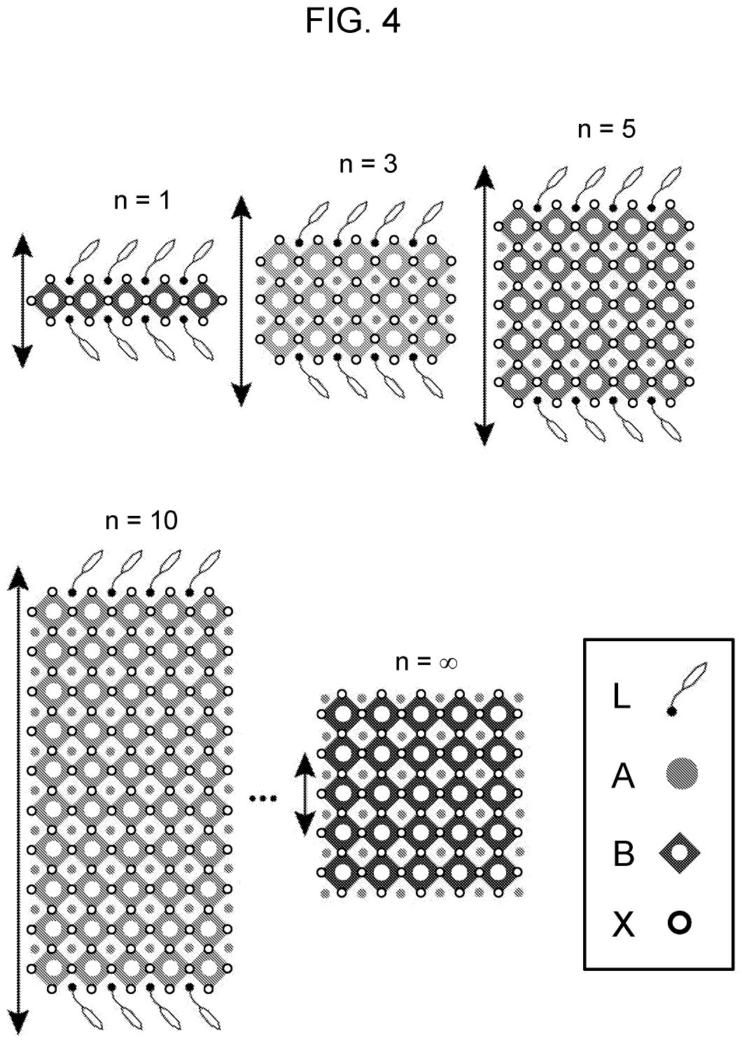

FIG. 2 shows an inverted light emitting device 200 with a single emissive unit. The light emitting device 200 may be a PeLED, OLED or QLED. The device includes a substrate 210, a cathode 215, an emissive layer 220, a hole transport layer 225, and an anode 230. Device 200 may be fabricated by depositing the layers described in order. As the device 200 has cathode 215 disposed under anode 230, device 200 may be referred to as an “inverted” device architecture. For a PeLED, the emissive layer comprises perovskite light emitting material. For an OLED, the emissive layer comprises organic light emitting material. For a QLED, the emissive layer comprises quantum dot light emitting material. Materials similar to those described with respect to device 100 may be used in the corresponding layers of device 200. FIG. 2 provides one example of how some layers may be omitted from the structure of a PeLED, OLED or QLED.

The simple layered structures illustrated in FIGS. 1 and 2 are provided by way of non-limiting examples, and it is understood that embodiments of the invention may be used in connection with a wide variety of other structures. The specific materials and structures described are exemplary in nature, and other materials and structures may be used. Functional PeLEDs, OLEDs and QLEDs may be achieved by combining the various layers described in different ways, or layers may be omitted entirely, based on factors such as performance, design and cost. Other layers, not specifically described, may also be included. Materials other than those specifically described may be used. Although many of the examples provided herein describe various layers as comprising a single material, it is understood that combinations of materials may be used. Also, the layers may have various sublayers. The names given to the various layers herein are not intended to be strictly limiting. For example, in a device, the hole transport layer may transport and inject holes into the emissive layer and may be described as a hole transport layer or a hole injection layer. PeLEDs, OLEDs and QLEDs are generally intended to emit light through at least one of the electrodes, and one or more transparent electrodes may be useful in such optoelectronic devices. For example, a transparent electrode material, such as indium tin oxide (ITO), may be used for the bottom electrode, while a transparent electrode material, such as a thin metallic layer of a blend of magnesium and silver (Mg:Ag), may be used for the top electrode. For a device intended to emit light only through the bottom electrode, the top electrode does not need to be transparent, and may be comprised of an opaque and/or reflective layer, such as a metal layer having a high reflectivity. Similarly, for a device intended only to emit light through the top electrode, the bottom electrode may be opaque and/or reflective, such as a metal layer having a high reflectivity. Where an electrode does not need to be transparent, using a thicker layer may provide better conductivity and may reduce voltage drop and/or Joule heating in the device, and using a reflective electrode may increase the amount of light emitted through the other electrode by reflecting light back towards the transparent electrode. A fully transparent device may also be fabricated, where both electrodes are transparent.

Devices fabricated in accordance with embodiments of the present invention may optionally comprise a substrate 110. The substrate 110 may comprise any suitable material that provides the desired structural and optical properties. The substrate 110 may be rigid or flexible. The substrate 110 may be flat or curved. The substrate 110 may be transparent, translucent or opaque. Preferred substrate materials are glass, plastic and metal foil. Other substrates, such as fabric and paper may be used. The material and thickness of the substrate 110 may be chosen to obtain desired structural and optical properties. Substantial similarity between substrate properties required for PeLEDs, OLEDs and QLEDs facilitates the combination of perovskite light emitting material, organic light emitting material and quantum dot light emitting material in a single device, such as a stacked light emitting device.

Devices fabricated in accordance with embodiments of the present invention may optionally comprise an anode 115. The anode 115 may comprise any suitable material or combination of materials known to the art, such that the anode 115 is capable of conducting holes and injecting them into the layers of the device. Preferred anode 115 materials include conductive metal oxides, such as indium tin oxide (ITO), indium zinc oxide (IZO) and aluminum zinc oxide (AlZnO), metals such as silver (Ag), aluminum (Al), aluminum-neodymium (Al:Nd), gold (Au) and alloys thereof, or a combination thereof. Other preferred anode 115 materials include graphene, carbon nanotubes, nanowires or nanoparticles, silver nanowires or nanoparticles, organic materials, such as poly(3,4-ethylenedioxythiophene): polystyrene sulfonate (PEDOT:PSS) and derivatives thereof, or a combination thereof. Compound anodes comprising one or more anode materials in a single layer may be preferred for some devices. Multilayer anodes comprising one or more anode materials in one or more layers may be preferred for some devices. One example of a multilayer anode is ITO/Ag/ITO. In a standard device architecture for PeLEDs, OLEDs and QLEDs, the anode 115 may be sufficiently transparent to create a bottom-emitting device, where light is emitted through the substrate. One example of a transparent anode commonly used in a standard device architecture is a layer of ITO. Another example of a transparent anode commonly used in a standard device architecture is ITO/Ag/ITO, where the Ag thickness is less than approximately 25 nm. By including a layer of silver of thickness less than approximately 25 nm, the anode may be transparent as well as partially reflective. When such a transparent and partially reflective anode is used in combination with a reflective cathode, such as LiF/AI, this may have the advantage of creating a microcavity within the device. A microcavity may provide one or more of the following advantages: an increased total amount of light emitted from device, and therefore higher efficiency and brightness; an increased proportion of light emitted in the forward direction, and therefore increased apparent brightness at normal incidence; and spectral narrowing of the emission spectrum, resulting in light emission with increased colour saturation. The anode 115 may be opaque and/or reflective. In a standard device architecture for PeLEDs, OLEDs and QLEDs, a reflective anode 115 may be preferred for some top-emitting devices to increase the amount of light emitted from the top of the device. One example of a reflective anode commonly used in a standard device architecture is a multilayer anode of ITO/Ag/ITO, where the Ag thickness is greater than approximately 80 nm. When such a reflective anode is used in combination with a transparent and partially reflective cathode, such as Mg:Ag, this may have the advantage of creating a microcavity within the device. The material and thickness of the anode 115 may be chosen to obtain desired conductive and optical properties. Where the anode 115 is transparent, there may be a range of thicknesses for a particular material that is thick enough to provide the desired conductivity, yet thin enough to provide the desired degree of transparency. Other materials and structures may be used. Substantial similarity between anode properties required for PeLEDs, OLEDs and QLEDs facilitates the combination of perovskite light emitting material, organic light emitting material and quantum dot light emitting material in a single device, such as a stacked light emitting device.

Devices fabricated in accordance with embodiments of the present invention may optionally comprise a hole transport layer 125. The hole transport layer 125 may include any material capable of transporting holes. The hole transport layer 125 may be deposited by a solution process or by a vacuum deposition process. The hole transport layer 125 may be doped or undoped. Doping may be used to enhance conductivity.

Examples of undoped hole transport layers are N,N′-Di(1-naphthyl)-N,N′-diphenyl-(1,1′-biphenyl)-4,4′-diamine (NPD), poly[(9,9-dioctylfluorenyl-2,7-diyl)-co-(4,4′-(N-(4-sec-butylphenyl) diphenylamine (TFB), poly[N,N′-bis(4-butylphenyl)-N,N′-bis(phenyl)-benzidine](poly-TPD), poly(9-vinylcarbazole) (PVK), 4,4′-Bis(N-carbazolyl)-1,1′-biphenyl (CBP), Spiro-OMeTAD and molybdenum oxide (MoO₃). One example of a doped hole transport layer is 4,4′,4″-Tris[phenyl(m-tolyl)amino]triphenylamine (m-MTDATA) doped with F₄-TCNQ at a molar ratio of 50:1. One example of a solution-processed hole transport layer is PEDOT:PSS. Other hole transport layers and structures may be used. The preceding examples of hole transport materials are especially well-suited to application in PeLEDs. However, these materials may also be implemented effectively in OLEDs and QLEDs. Substantial similarity between hole transport layer properties required for perovskite light emitting material, organic light emitting material and quantum dot light emitting material facilitates the combination of these light emitting materials in a single device, such as a stacked light emitting device.

Devices fabricated in accordance with embodiments of the present invention may optionally comprise an emissive layer 135. The emissive layer 135 may include any material capable of emitting light when a current is passed between anode 115 and cathode 155. Device architectures and operating principles are substantially similar for PeLEDs, OLEDs and QLEDs. However, these light emitting devices may be distinguished by differences in their respective emissive layers. The emissive layer of a PeLED may comprise perovskite light emitting material. The emissive layer of an OLED may comprise organic light emitting material. The emissive layer of a QLED may comprise quantum dot light emitting material.

Examples of perovskite light-emitting materials include 3D perovskite materials, such as methylammonium lead iodide (CH₃NH₃PbI₃), methylammonium lead bromide (CH₃NH₃PbBr₃), methylammonium lead chloride (CH₃NH₃PbCl₃), formamidinium lead iodide (CH(NH₂)₂PbI₃), formamidinium lead bromide (CH(NH₂)₂PbBr₃), formamidinium lead chloride (CH(NH₂)₂PbCl₃), caesium lead iodide (CsPbI₃), caesium lead bromide (CsPbBr₃) and caesium lead chloride (CsPbCl₃). Examples of perovskite light-emitting materials further include 3D perovskite materials with mixed halides, such as CH₃NH₃PbI₃₋ₓClₓ, CH₃NH₃PbI₃₋ₓBrₓ, CH₃NH₃PbCl₃₋ₓBrₓ, CH(NH₂)₂PbI₃₋ₓBrₓ, CH(NH₂)₂PbI₃₋ₓClₓ, CH(NH₂)₂PbCl₃₋ₓBrₓ, CsPbI₃₋ₓClₓ, CsPbI₃₋ₓBrₓ and CsPbCl₃₋ₓBrₓ, where x is in the range of 0-3. Examples of perovskite light-emitting materials further include 2D perovskite materials such as (C₁₀H₂CH₂NH₃)₂PbI₄, (C₁₀H₇CH₂NH₃)₂PbBr₄, (C₁₀H₂CH₂NH₃)₂PbCl₄, (C₆H₅C₂H₄NH₃)₂PbI₄, (C₆H₅C₂H₄NH₃)₂PbBr₄ and (C₆H₅C₂H₄NH₃)₂PbCl₄, 2D perovskite materials with mixed halides, such as (C₁₀H₂CH₂NH₃)₂PbI₃₋ₓClₓ, (C₁₀H₂CH₂NH₃)₂PbI₃₋ₓBrₓ, (C₁₀H₂CH₂NH₃)₂PbCl₃₋ₓBrₓ, (C₆H₅C₂H₄NH₃)₂PbI₃₋ₓClₓ, (C₆H₅C₂H₄NH₃)₂PbI₃₋ₓBrₓ and (C₆H₅C₂H₄NH₃)₂PbCl₃₋ₓBrₓ, where x is in the range of 0-3. Examples of perovskite light-emitting materials further include Quasi-2D perovskite materials, such as (C₆H₅C₂H₄NH₃)₂(CH(NH₂)₂PbBr₃)ₙ₋₁PbI₄, (C₆H₅C₂H₄NH₃)₂(CH(NH₂)₂PbBr₃)ₙ₋₁PbBr₄, (C₆H₅C₂H₄NH₃)₂(CH(NH₂)₂PbBr₃)ₙ₋₁PbCl₄, (C₁₀H₂CH₂NH₃)₂(CH₃NH₃PbI₂Br)ₙ₋₁PbI₄, (C₁₀H₂CH₂NH₃)₂(CH₃NH₃PbI₂Br)ₙ₋₁PbBr₄ and (C₁₀H₂CH₂NH₃)₂(CH₃NH₃PbI₂Br)ₙ₋₁PbCl₄, where n is the number of layers, and, optionally, n may be in the range of about 2-10. Examples of perovskite light-emitting materials further include Quasi-2D perovskite materials with mixed halides, such as (C₆H₅C₂H₄NH₃)₂(CH(NH₂)₂PbBr₃)ₙ₋₁PbI₃₋ₓClₓ, (C₆H₅C₂H₄NH₃)₂(CH(NH₂)₂PbBr₃)ₙ₋₁PbI₃₋ₓBrₓ, (C₆H₅C₂H₄NH₃)₂(CH(NH₂)₂PbBr₃)ₙ₋₁PbCl₃₋ₓBrₓ, (C₁₀H₇CH₂NH₃)₂(CH₃NH₃PbI₂Br)ₙ₋₁PbI₃₋ₓClₓ, (C₁₀H₇CH₂NH₃)₂(CH₃NH₃PbI₂Br)ₙ₋₁PbI₃,Brₓ and (C₁₀H₇CH₂NH₃)₂(CH₃NH₃PbI₂Br)ₙ₋₁PbCl₃₋ₓBrₓ, where n is the number of layers, and, optionally, n may be in the range of about 2-10, and x is in the range of 0-3. Examples of perovskite light-emitting materials further include any of the aforementioned examples, where the divalent metal cation lead (Pb⁺) may be replaced with tin (Sn⁺), copper (Cu⁺) or europium (Eu⁺). Examples of perovskite light-emitting materials further include perovskite light-emitting nanocrystals with structures that closely resemble Quasi-2D perovskite materials.

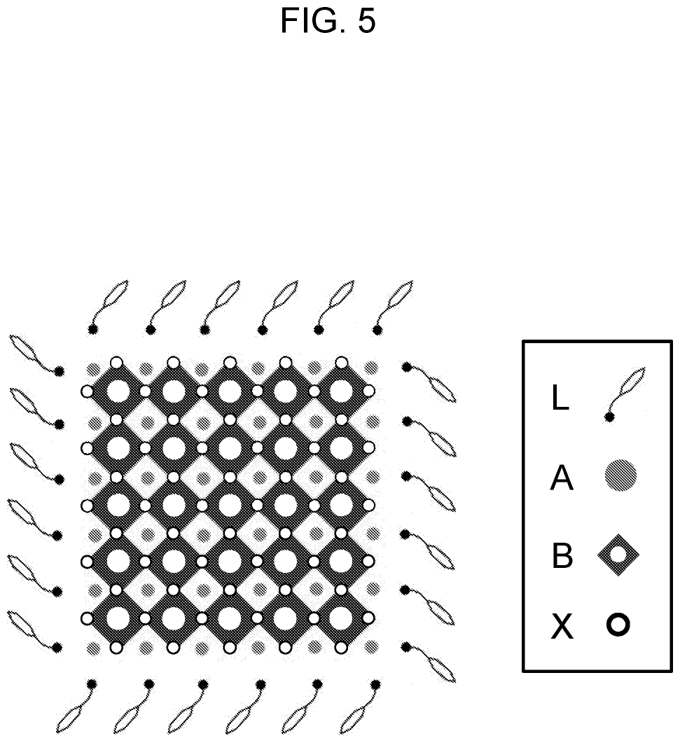

Perovskite light emitting material may comprise organic metal halide perovskite material, such as methylammonium lead iodide (CH₃NH₃PbI₃), methylammonium lead bromide (CH₃NH₃PbBr₃), methylammonium lead chloride (CH₃NH₃PbCl₃), where the materials comprises an organic cation. Perovskite light emitting material may comprise inorganic metal halide perovskite material, such as caesium lead iodide (CsPbI₃), caesium lead bromide (CsPbBr₃) and caesium lead chloride (CsPbCl₃), where the material comprises an inorganic cation. Furthermore, perovskite light emitting material may comprise perovskite light emitting material where there is a combination of organic and inorganic cations. The choice of an organic or inorganic cation may be determined by several factors, including desired emission colour, efficiency of electroluminescence, stability of electroluminescence and ease of processing. Inorganic metal halide perovskite material may be particularly well-suited to perovskite light-emitting materials with a nanocrystal structure, such as those depicted in FIG. 5, wherein an inorganic cation may enable a compact and stable perovskite light-emitting nanocrystal structure.

Perovskite light emitting material may be included in the emissive layer 135 in a number of ways. For example, the emissive layer may comprise 2D perovskite light-emitting material, Quasi-2D perovskite light-emitting material or 3D perovskite light-emitting material, or a combination thereof. Optionally, the emissive layer may comprise perovskite light emitting nanocrystals. Optionally, the emissive layer 135 may comprise an ensemble of Quasi-2D perovskite light emitting materials, where the Quasi-2D perovskite light emitting materials in the ensemble may comprise a different number of layers. An ensemble of Quasi-2D perovskite light emitting materials may be preferred because there may be energy transfer from Quasi-2D perovskite light emitting materials with a smaller number of layers and a larger energy band gap to Quasi-2D perovskite light emitting materials with a larger number of layers and a lower energy band gap. This energy funnel may efficiently confine excitons in a PeLED device, and may improve device performance. Optionally, the emissive layer 135 may comprise perovskite light emitting nanocrystal materials. Perovskite light emitting nanocrystal materials may be preferred because nanocrystal boundaries may be used to confine excitons in a PeLED device, and surface cations may be used to passivate the nanocrystal boundaries. This exciton confinement and surface passivation may improve device performance. Other emissive layer materials and structures may be used.

Several examples of fluorescent organic light emitting materials are described in European patent EP 0423283 B1. Several examples of phosphorescent organic light emitting materials are described in U.S. Pat. Nos. 6,303,238 B1 and 7,279,704 B2. Several examples of organic light emitting materials that emit through a TADF mechanism are described in Uoyama et al. Several examples of quantum dot light emitting materials are described in Kathirgamanathan et al. (1). All of these citations are included herein by reference in their entirety.

Devices fabricated in accordance with embodiments of the present invention may optionally comprise an electron transport layer 145. The electron transport layer 145 may include any material capable of transporting electrons. The electron transport layer 145 may be deposited by a solution process or by a vacuum deposition process. The electron transport layer 145 may be doped or undoped. Doping may be used to enhance conductivity.

Examples of undoped electron transport layers are tris(8-hydroxyquinolinato)aluminum (Alq₃), 2,2′,2″-(1,3,5-Benzinetriyl)-tris(1-phenyl-1-H-benzimidazole) (TPBi), 2,9-Dimethyl-4,7-diphenyl-1,10-phenanthroline (BCP), zinc oxide (ZnO) and titanium dioxide (TiO₃). One example of a doped electron transport layer is 4,7-diphenyl-1,10-phenanthroline (BPhen) doped with lithium (Li) at a molar ratio of 1:1. One example of a solution-processed electron transport layer is [6,6]-Phenyl C61 butyric acid methyl ester (PCBM). Other electron transport layers and structures may be used. The preceding examples of electron transport materials are especially well-suited to application in PeLEDs. However, these materials may also be implemented effectively in OLEDs and QLEDs. Substantial similarity between electron transport layer properties required for perovskite light emitting material, organic light emitting material and quantum dot light emitting material facilitates the combination of these light emitting materials in a single device, such as a stacked light emitting device.

Devices fabricated in accordance with embodiments of the present invention may optionally comprise a cathode 155. The cathode 155 may comprise any suitable material or combination of materials known to the art, such that the cathode 155 is capable of conducting electronics and injecting them into the layers of the device. Preferred cathode 155 materials include metal oxides, such as indium tin oxide (ITO), indium zinc oxide (IZO) and fluorine tin oxide (FTO), metals, such as calcium (Ca), barium (Ba), magnesium (Mg) and ytterbium (Yb) or a combination thereof. Other preferred cathode 155 materials include metals such as silver (Ag), aluminum (Al), aluminum-neodymium (Al:Nd), gold (Au) and alloys thereof, or a combination thereof. Compound cathodes comprising one or more cathode materials in a single layer may be preferred from some devices. One example of a compound cathode is Mg:Ag. Multilayer cathodes comprising one or more cathode materials in one or more layers may be preferred for some devices. One example of a multilayer cathode is Ba/Al. In a standard device architecture for PeLEDs, OLEDs and QLEDs, the cathode 155 may be sufficiently transparent to create a top-emitting device, where light is emitted from the top of the device. One example of a transparent cathode commonly used in a standard device architecture is a compound layer of Mg:Ag. By using a compound of Mg:Ag, the cathode may be transparent as well as partially reflective. When such a transparent and partially reflective cathode is used in combination with a reflective anode, such as ITO/Ag/ITO, where the Ag thickness is greater than approximately 80 nm, this may have the advantage of creating a microcavity within the device. The cathode 155 may be opaque and/or reflective. In a standard device architecture for PeLEDs, OLEDs and QLEDs, a reflective cathode 155 may be preferred for some bottom-emitting devices to increase the amount of light emitted through the substrate from the bottom of the device. One example of a reflective cathode commonly used in a standard device architecture is a multilayer cathode of LiF/Al. When such a reflective cathode is used in combination with a transparent and partially reflective anode, such as ITO/Ag/ITO, where the Ag thickness is less than approximately 25 nm, this may have the advantage of creating a microcavity within the device.

The material and thickness of the cathode 155 may be chosen to obtain desired conductive and optical properties. Where the cathode 155 is transparent, there may be a range of thicknesses for a particular material that is thick enough to provide the desired conductivity, yet thin enough to provide the desired degree of transparency. Other materials and structures may be used. Substantial similarity between cathode properties required for PeLEDs, OLEDs and QLEDs facilitates the combination of perovskite light emitting material, organic light emitting material and quantum dot light emitting material in a single device, such as a stacked light emitting device.

Devices fabricated in accordance with embodiments of the present invention may optionally comprise one or more blocking layers. Blocking layers may be used to reduce the number of charge carriers (electrons or holes) and/or excitons exiting the emissive layer. An electron blocking layer 130 may be disposed between the emissive layer 135 and the hole transport layer 125 to block electrons from leaving the emissive layer 135 in the direction of the hole transport layer 125. Similarly, a hole blocking layer 140 may be disposed between the emissive layer 135 and the electron transport layer 145 to block holes from leaving the emissive layer 135 in the direction of the electron transport layer 145. Blocking layers may also be used to block excitons from diffusing from the emissive layer. As used herein, and as would be understood by one skilled in the art, the term “blocking layer” means that the layer provides a barrier that significantly inhibits transport of charge carriers and/or excitons, without suggesting that the layer completely blocks the charge carriers and/or excitons. The presence of such a blocking layer in a device may result in substantially higher efficiencies as compared to a similar device lacking a blocking layer. A blocking layer may also be used to confine emission to a desired region of a device. Substantial similarity between blocking layer properties required for perovskite light emitting material, organic light emitting material and quantum dot light emitting material facilitates the combination of these light emitting materials in a single device, such as a stacked light emitting device.

Devices fabricated in accordance with embodiments of the present invention may optionally comprise one or more injection layers. Generally, injection layers are comprised of one or more materials that may improve the injection of charge carriers from one layer, such as an electrode, into an adjacent layer. Injection layers may also perform a charge transport function.

In device 100, the hole injection layer 120 may be any layer that improves the injection of holes from the anode 115 into the hole transport layer 125. Examples of materials that may be used as a hole injection layer are Copper(II)phthalocyanine (CuPc) and 1,4,5,8,9,11-Hexaazatriphenylenehexacarbonitrile (HATCN), which may be vapor deposited, and polymers, such as PEDOT:PSS, which may be deposited from solution. Another example of a material that may be used as a hole injection layer is molybdenum oxide (MoO₃). The preceding examples of hole injection materials are especially well-suited to application in PeLEDs. However, these materials may also be implemented effectively in OLEDs and QLEDs. Substantial similarity between hole injection layer properties required for perovskite light emitting material, organic light emitting material and quantum dot light emitting material facilitates the combination of these light emitting materials in a single device, such as a stacked light emitting device.

A hole injection layer (HIL) 120 may comprise a charge carrying component having HOMO energy level that favourably matches, as defined by their herein-described relative IP energies, with the adjacent anode layer on one side of the HIL, and the hole transporting layer on the opposite side of the HIL. The “charge carrying component” is the material responsible for the HOMO energy level that actually transports the holes. This material may be the base material of the HIL, or it may be a dopant. Using a doped HIL allows the dopant to be selected for its electrical properties, and the host to be selected for morphological properties, such as ease of deposition, wetting, flexibility, toughness, and others. Preferred properties of the HIL material are such that holes can be efficiently injected from the anode into the HIL material. The charge carrying component of the HIL 120 preferably has an IP not more than about 0.5 eV greater than the IP of the anode material. Similar conditions apply to any layer into which holes are being injected. HIL materials are further distinguished from conventional hole transporting materials that are typically used in the hole transporting layer of a PeLED, OLED or QLED in that such HIL materials may have a hole conductivity that is substantially less than the hole conductivity of conventional hole transporting materials. The thickness of the HIL 120 of the present invention may be thick enough to planarize the anode and enable efficient hole injection, but thin enough not to hinder transportation of holes. For example, an HIL thickness of as little as 10 nm may be acceptable. However, for some devices, an HIL thickness of up to 50 nm may be preferred.

In device 100, the electron injection layer 150 may be any layer that improves the injection of electrons from the cathode 155 into the electron transport layer 145. Examples of materials that may be used as an electron injection layer are inorganic salts, such as lithium fluoride (LiF), sodium fluoride (NaF), barium fluoride (BaF), caesium fluoride (CsF), and caesium carbonate (CsCO₃). Other examples of materials that may be used as an electron injection layer are metal oxides, such as zinc oxide (ZnO) and titanium oxide (TiO₂), and metals, such as calcium (Ca), barium (Ba), magnesium (Mg) and ytterbium (Yb). Other materials or combinations of materials may be used for injection layers. Depending on the configuration of a particular device, injection layers may be disposed at locations different than those shown in device 100. The preceding examples of electron injection materials are all especially well-suited to application in PeLEDs. However, these materials may also be implemented effectively in OLEDs and QLEDs. Substantial similarity between electron injection layer properties required for perovskite light emitting material, organic light emitting material and quantum dot light emitting material facilitates the combination of these light emitting materials in a single device, such as a stacked light emitting device.

Devices fabricated in accordance with embodiments of the present invention may optionally comprise a capping layer 160. The capping layer 160 may include any material capable of enhancing light extraction from the device. Preferably, the capping layer 160 is disposed over the top electrode in a top-emitting device architecture. Preferably, the capping layer 160 has a refractive index of at least 1.7, and is configured to enhance passage of light from the emissive layer 135 through the top electrode and out of the device, thereby enhancing device efficiency. Examples of materials that may be used for the capping layer 160 are 4,4′-Bis(N-carbazolyl)-1,1′-biphenyl (CBP), Alq₃, and more generally, triamines and arylenediamines. The capping layer 160 may comprise a single layer or multiple layers. Other capping layer materials and structures may be used. Substantial similarity between capping layer properties required for perovskite light emitting materials, organic light emitting materials and quantum dot light emitting materials facilitates the combination of these light emitting devices in a single device, such as a stacked light emitting device.

Devices fabricated in accordance with embodiments of the present invention may optionally comprise a barrier layer 165. One purpose of the barrier layer 165 is to protect device layers from damaging species in the environment, including moisture, vapour and/or gasses. Optionally, the barrier layer 165 may be deposited over, under or next to the substrate, electrode, or any other parts of the device, including an edge. Optionally, the barrier layer 165 may be a bulk material such as glass or metal, and the bulk material may be affixed over, under of next to the substrate, electrode, or any other parts of the device. Optionally, the barrier layer 165 may be deposited onto a film, and the film may be affixed over, under of next to the substrate, electrode, or any other parts of the device. Where the barrier layer 165 is deposited onto a film, preferred film materials comprise glass, plastics, such as polyethylene terephthalate (PET) and polyethylene naphthalate (PEN) and metal foils. Where the barrier layer 165 is a bulk material or deposited onto a film, preferred materials used to affix the film or bulk material to the device include thermal or UV-curable adhesives, hot-melt adhesives and pressure sensitive adhesives.

The barrier layer 165 may be a bulk material or formed by various known deposition techniques, including sputtering, vacuum thermal evaporation, electron-beam deposition and chemical vapour deposition (CVD) techniques, such as plasma-enhanced chemical vapour deposition (PECVD) and atomic layer deposition (ALD). The barrier layer 165 may include compositions having a single phase as well as compositions having multiple phases. Any suitable material or combination of materials may be used for the barrier layer 165. The barrier layer 165 may incorporate organic or inorganic compounds or both. Preferred inorganic barrier layer materials include aluminum oxides such as Al₂O₃, silicon oxides such as SiO₂, silicon nitrides such as SiNₓ and bulk materials such as glasses and metals. Preferred organic barrier layer materials include polymers. The barrier layer 165 may comprise a single layer or multiple layers. Multilayer barriers comprising one or more barrier materials in one or more layers may be preferred for some devices. One preferred example of a multilayer barrier is a barrier comprising alternating layers of SiNₓ and a polymer, such as in the multilayer barrier SiNₓ/polymer/SiNₓ. Substantial similarity between barrier layer properties required for perovskite light emitting material, organic light emitting material and quantum dot light emitting material facilitates the combination of these light emitting materials in a single device, such as a stacked light emitting device.

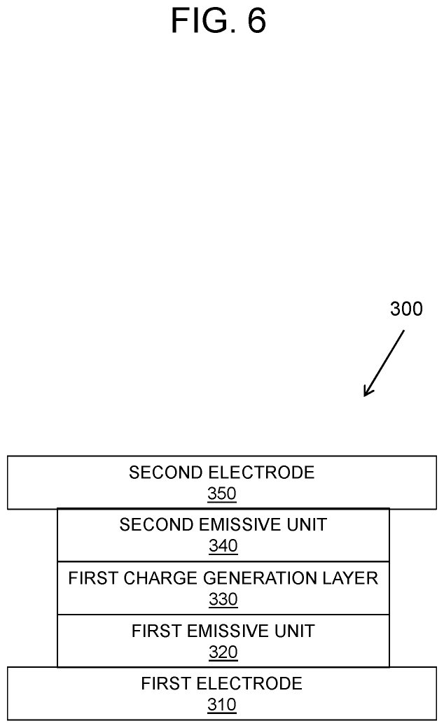

FIG. 6 shows a stacked light emitting device 300 having two emissive units. The light emitting device 300 may comprise one or more PeLED, OLED or QLED emissive units. Device 300 may include a first electrode 310, a first emissive unit 320, a first charge generation layer 330, a second emissive unit 340, and a second electrode 350. Device 300 may be fabricated by depositing the layers described in order. For a PeLED emissive unit, the emissive unit comprises perovskite light emitting material. For an OLED emissive unit, the emissive unit comprises organic light emitting material. For a QLED emissive unit, the emissive unit comprises quantum dot light emitting material.

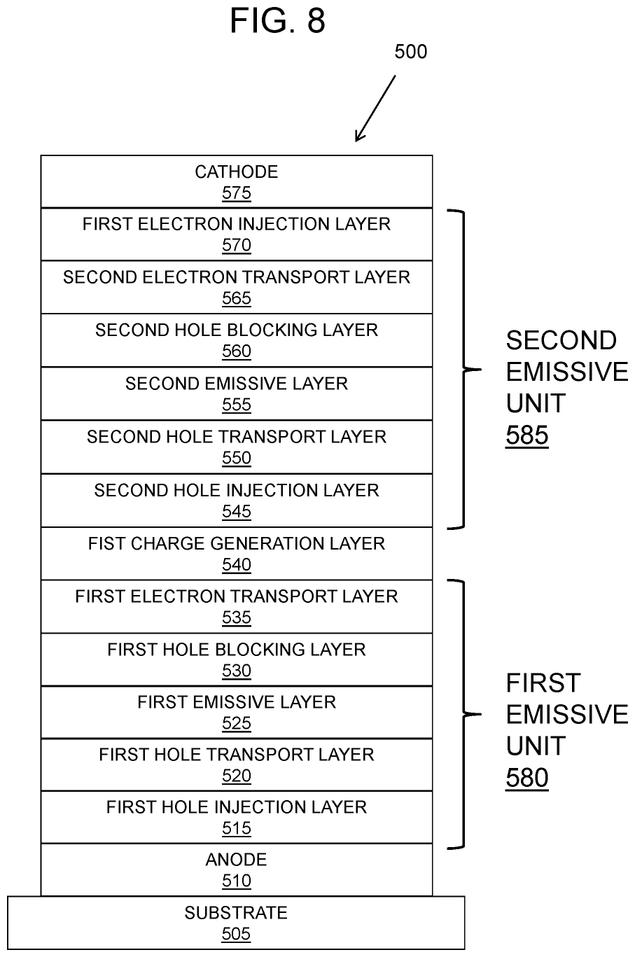

FIG. 8 depicts a layer structure for a stacked light emitting device 500 having two emissive units. The light emitting device 500 may comprise one or more PeLED, OLED or QLED emissive units. Device 500 may include a substrate 505, an anode 510, a first hole injection layer 515, a first hole transport layer 520, a first emissive layer 525, a first hole blocking layer 530, a first electron transport layer 535, a first charge generation layer 540, a second hole injection layer 545, a second hole transport layer 550, a second emissive layer 555, a second hole blocking layer 560, a second electron transport layer 565, a first electron injection layer 570, and a cathode 575. The first emissive unit 580 may comprise the first hole injection layer 515, the first hole transport layer 520, the first emissive layer 525, the first hole blocking layer 530, and the first electron transport layer 535. The second emissive unit 585 may comprise the second hole injection layer 545, the second hole transport layer 550, the second emissive layer 555, the second hole blocking layer 560, the second electron transport layer 565, and the first electron injection layer 570. Device 500 may be fabricated by depositing the layers described in order. For a PeLED emissive unit, the emissive unit comprises perovskite light emitting material. For an OLED emissive unit, the emissive unit comprises organic light emitting material. For a QLED emissive unit, the emissive unit comprises quantum dot light emitting material.

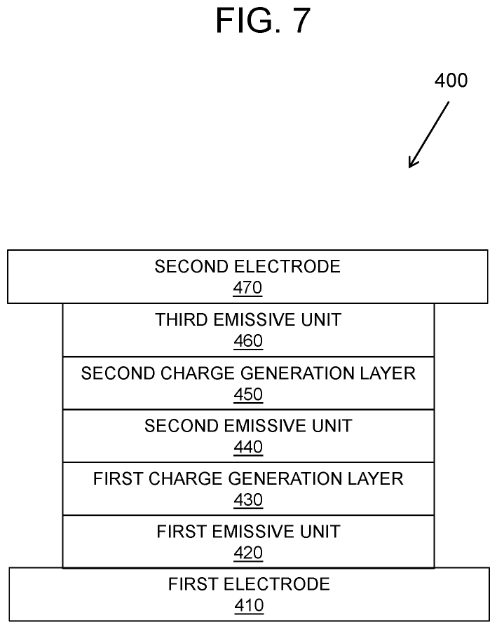

FIG. 7 shows a stacked light emitting device 400 having three emissive units. The light emitting device 400 may comprise one or more PeLED, OLED or QLED emissive units. Device 400 may include a first electrode 410, a first emissive unit 420, a first charge generation layer 430, a second emissive unit 440, a second charge generation layer 450, a third emissive unit 460, and a second electrode 470. Device 400 may be fabricated by depositing the layers described in order. For a PeLED emissive unit, the emissive unit comprises perovskite light emitting material. For an OLED emissive unit, the emissive unit comprises organic light emitting material. For a QLED emissive unit, the emissive unit comprises quantum dot light emitting material.

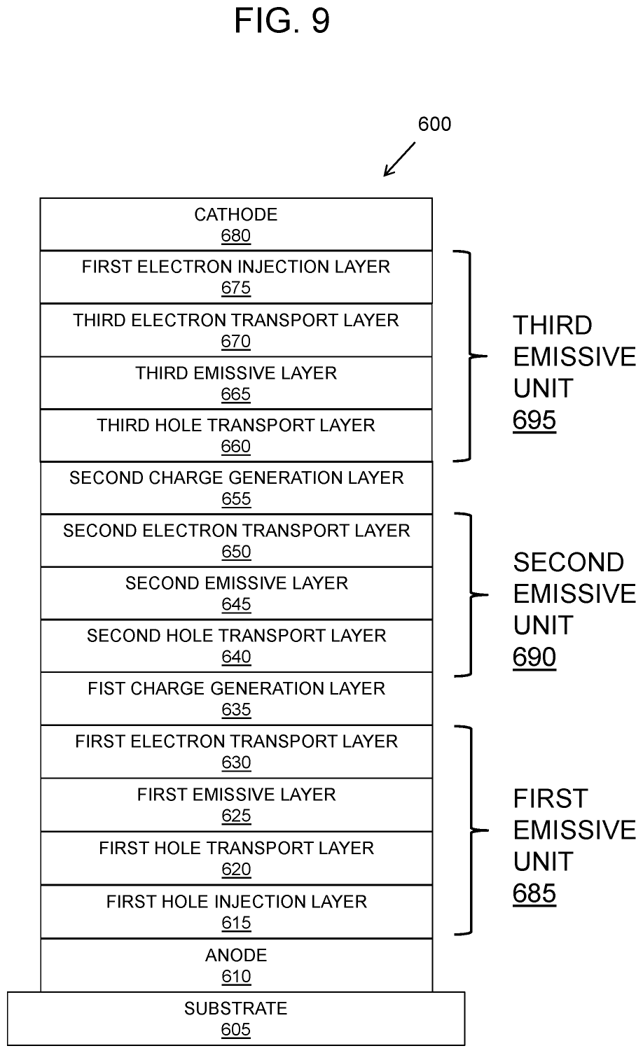

FIG. 9 depicts a layer structure for a stacked light emitting device 600 having three emissive units. The light emitting device 600 may comprise one or more PeLED, OLED or QLED emissive units. Device 600 may include a substrate 605, an anode 610, a first hole injection layer 615, a first hole transport layer 620, a first emissive layer 625, a first electron transport layer 630, a first charge generation layer 635, a second hole transport layer 640, a second emissive layer 645, a second electron transport layer 650, a second charge generation layer 655, a third hole transport layer 660, a third emissive layer 665, a third electron transport layer 670, a first electron injection layer 675, and a cathode 680. The first emissive unit 685 may comprise the first hole injection layer 615, the first hole transport layer 620, the first emissive layer 625, and the first electron transport layer 630. The second emissive unit 690 may comprise the second hole transport layer 640, the second emissive layer 645, and the second electron transport layer 650. The third emissive unit 695 may comprise the third hole transport layer 660, the third emissive layer 665, the third electron transport layer 670, and the first electron injection layer 675. Device 600 may be fabricated by depositing the layers described in order. For a PeLED emissive unit, the emissive unit comprises perovskite light emitting material. For an OLED emissive unit, the emissive unit comprises organic light emitting material. For a QLED emissive unit, the emissive unit comprises quantum dot light emitting material. FIG. 9 provides one example of how some layers may be omitted from one or more emissive units of a stacked light emitting device.

The simple layered structures illustrated in FIGS. 8 and 9 are provided by way of non-limiting examples, and it is understood that embodiments of the invention may be used in connection with a wide variety of other structures. The specific materials and structures described are exemplary in nature, and other materials and structures may be used. Functional light emitting devices may be achieved by combining the various layers described in different ways, or layers may be omitted entirely, based on factors such as performance, design and cost. Other layers, not specifically described, may also be included. Materials other than those specifically described may be used. Although many of the examples provided herein describe various layers as comprising a single material, it is understood that combinations of materials may be used. Also, the layers may have various sublayers. The names given to the various layers herein are not intended to be strictly limiting. For example, in a device, the electron transport layer may transport electrons into the emissive layer, and also block holes from exiting the emissive layer, and may be described as an electron transport layer or a hole blocking layer.

Stacked light emitting device architectures, as depicted in FIGS. 6, 7, 8 and 9, may provide one or more of the following advantages: light from multiple emissive units may be combined within the same surface area of the device, thereby increasing the brightness of the device; multiple emissive units may be connected electrically in series, with substantially the same current passing through each emissive unit, thereby allowing the device to operate at increased brightness without substantial increase in current density, thereby extending the operation lifetime of the device; and the amount of light emitted from separate emissive units may be separately controlled, thereby allowing the brightness and/or colour of the device to be tuned according to the needs of the application. Connection of the emissive units in series further allows for direct current (DC) to flow through each emissive unit within the stacked light emitting device. This enables the stacked light emitting device to have a simple two electronic terminal design that is compatible with standard thin film transistor (TFT) backplane designs, such as passive matrix and active matrix backplanes used to drive electronic displays.

Optionally, devices fabricated in accordance with embodiments of the present invention may comprise two emissive units. Optionally, devices fabricated in accordance with embodiments of the present invention may comprise three emissive units. Optionally, devices fabricated in accordance with embodiments of the present invention may comprise four or more emissive units.

Optionally, an emissive unit may comprise an emissive layer. Optionally, an emissive unit may further comprise one or more additional layers, such as a hole injection layer, a hole transport layer, an electron blocking layer, a hole blocking layer, an electron transport layer and/or an electron injection layer. Optionally, some of these additional layers may be included within an emissive unit, and some of these additional layers may be excluded.

Devices fabricated in accordance with embodiments of the present invention may optionally comprise one or more charge generation layers. Optionally, a charge generation layer may be used to separate two or more emissive units within a stacked light emitting device. Stacked light emitting device 300, depicted in FIG. 6, comprises a first charge generation layer 330, which separates a first emissive unit 320 from a second emissive unit 340. Stacked light emitting device 400, depicted in FIG. 7, comprises a first charge generation layer 430, which separates a first emissive unit 420 from a second emissive unit 440. Stacked light emitting device 400, depicted in FIG. 7, further comprises a second charge generation layer 450, which separates a second emissive unit 440 from a third emissive unit 460.

A charge generation layer 330, 430 or 450 may comprise a single layer or multiple layers. Optionally, a charge generation layer 330, 430 or 450 may comprise an n-doped layer for the injection of electrons, and a p-doped layer for the injection of holes. Optionally, a charge generation layer 330, 430 or 450 may include a hole injection layer (HIL). Optionally, a p-doped layer of charge generation layer 330, 430 or 450 may function as a hole injection layer (HIL). FIG. 9 depicts a stacked light emitting device 600 having three emissive units, where a first charge generation layer 635 includes a hole injection layer (not shown), and a second charge generation layer 655 includes a hole injection layer (not shown). Optionally, a charge generation layer 330, 430 or 450 may be positioned adjacent to and in contact with a separate hole injection layer. FIG. 8 depicts a stacked light emitting device 500 having two emissive units, where a first charge generation layer 540 is adjacent to and in contact with a second hole injection layer 545.

Optionally, a charge generation layer 330, 430 or 450 may include an electron injection layer (EIL). Optionally, an n-doped layer of charge generation layer 330, 430 or 450 may function as an electron injection layer (EIL). FIG. 9 depicts a stacked light emitting device 600 having three emissive units, where a first charge generation layer 635 includes an electron injection layer (not shown), and a second charge generation layer 655 includes an electron injection layer (not shown). Optionally, a charge generation layer 330, 430 or 450 may be positioned adjacent to and in contact with a separate electron injection layer.

A charge generation layer 330, 430 or 450 may be deposited by a solution process or by a vacuum deposition process. A charge generation layer 330, 430 or 450 may be composed of any applicable materials that enable injection of electrons and holes. A charge generation layer 330, 430 or 450 may be doped or undoped. Doping may be used to enhance conductivity.

One example of vapour process charge generation layer is a dual layer structure consisting of lithium doped BPhen (Li-BPhen) as the n-doped layer for electron injection, in combination with of 1,4,5,8,9,11-Hexaazatriphenylenehexacarbonitrile (HATCN) as the p-doped layer for hole injection. One example of a solution process charge generation layer is a dual layer structure consisting of polyethylenimine (PEI) surface modified zinc oxide (ZnO) as the n-doped layer for electron injection, in combination with molybdenum oxide (MoO₃) or tungsten trioxide (WO₃) as the p-doped layer for hole injection. Other materials or combinations of materials may be used for charge generation layers. Depending on the configuration of a particular device, charge generation layers may be disposed at locations different than those shown in device 500 and device 600. The preceding examples of charge generation layer materials are all especially well-suited to application in PeLEDs. However, these materials may also be implemented effectively in OLEDs and QLEDs. Substantial similarity between charge generation layer properties required for perovskite light emitting material, organic light emitting material and quantum dot light emitting material facilitates the combination of these light emitting materials in a single device, such as a stacked light emitting device.

Optionally, one or more charge generation layers within a stacked light emitting device may or may not be directly connected to one or more external electrical sources, and therefore may or may not be individually addressable. Connecting one or more charge generation layers to one or more external sources may be of advantage in that light emission from separate emissive units may be separately controlled, allowing the brightness and/or colour of a stacked light emitting device with multiple emissive units to be tuned according to the needs of the application. Not connecting one or more of the charge generation layers to one or more external sources may be of advantage in that the stacked light emitting device may then be a two terminal electronic device that is compatible with standard thin film transistor (TFT) backplane designs, such as passive matrix and active matrix backplanes used to drive electronic displays.

Devices fabricated in accordance with embodiments of the present invention may optionally comprise two or more emissive units separated by one or more charge generation layers. Optionally, the two or more emissive units and one or more charge generation layers may be vertically stacked within the device.

Unless otherwise specified, any one of the layers of the various embodiments may be deposited by any suitable method. Methods include vacuum thermal evaporation, sputtering, electron beam physical vapour deposition, organic vapor phase deposition and organic vapour jet printing. Other suitable methods include spincoating and other solution-based processes. Substantially similar processes can be used to deposit materials used in PeLED, OLED and QLED devices, which facilitates the combination of these materials in a single device, such as a stacked light emitting device.

Devices fabricated in accordance with embodiments of the invention may be incorporated into a wide range of consumer products. Optionally, devices may be used in displays for televisions, computer monitors, tablets, laptop computers, smart phones, cell phones, digital cameras, video recorders, smartwatches, fitness trackers, personal digital assistants, vehicle displays and other electronic devices. Optionally, devices may be used for micro-displays or heads-up displays. Optionally, devices may be used in light panels for interior or exterior illumination and/or signaling, in smart packaging or in billboards.

Optionally, various control mechanisms may be used to control light emitting devices fabricated in accordance with the present invention, including passive matrix and active matrix address schemes.

The materials and structures described herein may have applications in devices other than light emitting devices. For example, other optoelectronic devices such as solar cells, photodetectors, transistors or lasers may employ the materials and structures.

Layers, materials, regions, units and devices may be described herein in reference to the colour of light they emit. As used herein, a “red” layer, material, region, unit or device, refers to one that emits light that has an emission spectrum with a peak wavelength in the range of about 580-780 nm; a “green” layer, material, region, unit or device, refers to one that emits light that has an emission spectrum with a peak wavelength in the range of about 500-580 nm; a “blue” layer, material, region, unit or device, refers to one that emits light that has an emission spectrum with a peak wavelength in the range of about 380-500 nm; a “light blue” layer, material, region, unit or device, refers to one that emits light that has an emission spectrum with a peak wavelength in the range of about 460-500 nm; and a “yellow” layer, material, region, unit or device, refers to one that emits light that has an emission spectrum with a peak wavelength in the range of about 540-600 nm. Preferred ranges include a peak wavelength in the range of about 600-640 nm for red, about 510-550 nm for green, about 440-465 nm for blue, about 465-480 nm for light blue, and about 550-580 nm for yellow.

Similarly, any reference to a colour altering layer refers to a layer that converts or modifies another colour of light to light having a wavelength as specified for that colour. For example, a “red” color filter refers to a filter that results in light having an emission spectrum with a peak wavelength in the range of about 580-780 nm. In general, there are two classes of colour altering layers: colour filters that modify a spectrum by removing unwanted wavelengths of light, and colour changing layers that convert photons of higher energy to photons of lower energy.

Display technology is rapidly evolving, with recent innovations enabling thinner and lighter displays with higher resolution, improved frame rate and enhanced contrast ratio. However, one area where significant improvement is still required is colour gamut. Digital displays are currently incapable of producing many of the colours the average person experiences in day-to-day life. To unify and guide the industry towards improved colour gamut, two industry standards have been defined, DCI-P3 and Rec. 2020, with DCI-P3 often seen as a stepping stone towards Rec. 2020.

DCI-P3 was defined by the Digital Cinema Initiatives (DCI) organization and published by the Society of Motion Picture and Television Engineers (SMPTE). Rec. 2020 (more formally known as ITU-R Recommendation BT. 2020) was developed by the International Telecommunication Union to set targets, including improved colour gamut, for various aspects of ultra-high-definition televisions.

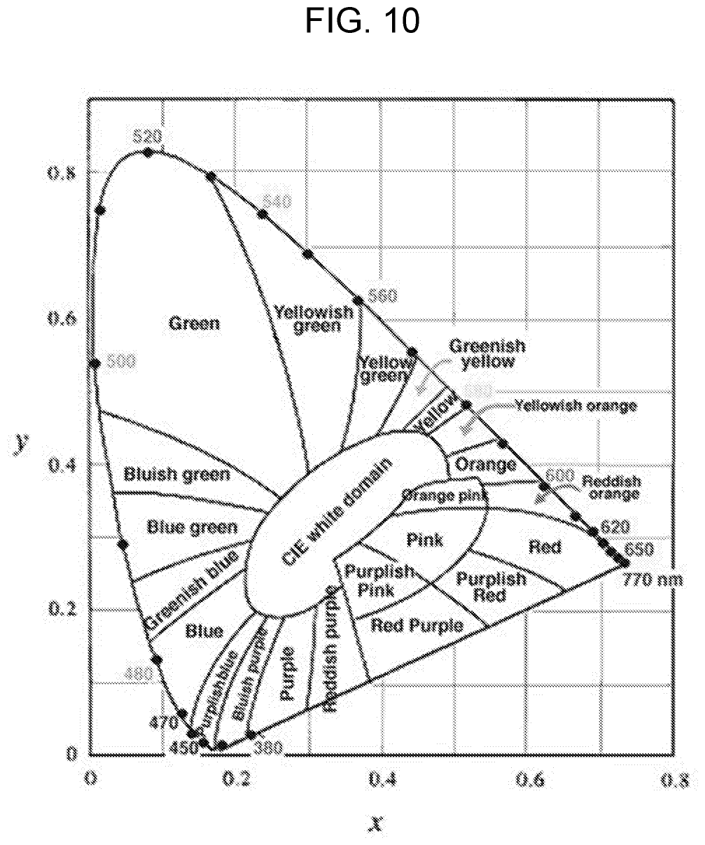

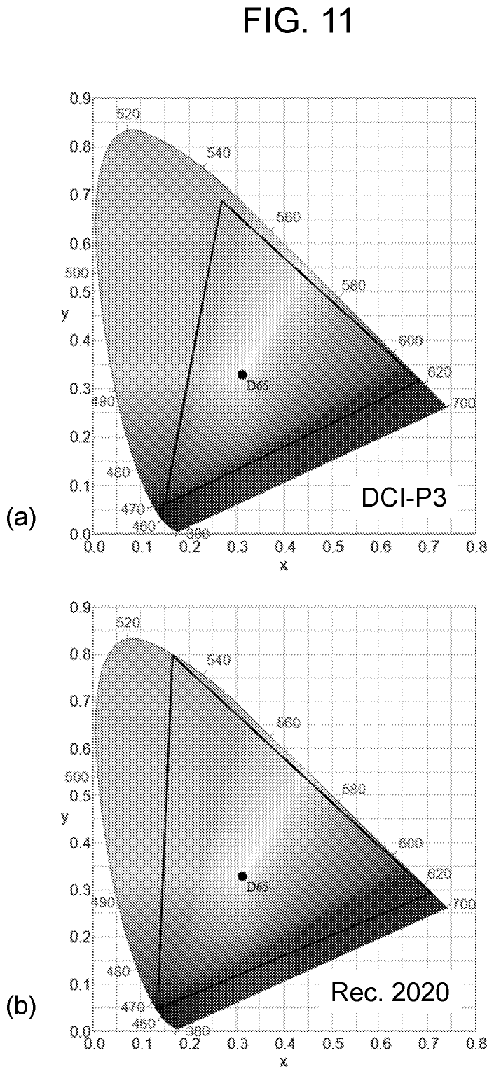

The CIE 1931 (x, y) chromaticity diagram was created by the Commission Internationale de l'Éclairage (CIE) in 1931 to define all colour sensations that an average person can experience. Mathematical relationships describe the location of each colour within the chromaticity diagram. The CIE 1931 (x, y) chromaticity diagram may be used to quantify the colour gamut of displays. The white point (D65) is at the centre, while colours become increasingly saturated (deeper) towards the extremities of the diagram. FIG. 10 shows the CIE 1931 (x, y) chromaticity diagram with labels added to different locations on the diagram to enable a general understanding of distribution of colour within the colour space. FIG. 11 shows (a) DCI-P3 and (b) Rec. 2020 colour spaces superimposed on the CIE 1931 (x, y) chromaticity diagram. The tips of the triangles are primary colours for DCI-P3 and Rec. 2020, respectively, while colours enclosed within the triangles are all the colours that can be reproduced by combining these primary colours. For a display to meet DCI-P3 colour gamut specifications, the red, green and blue sub-pixels of the display must emit light at least as deep in colour as the DCI-P3 primary colours. For a display to meet Rec. 2020 colour gamut specifications, the red, green and blue sub-pixels of the display must emit light at least as deep in colour as the Rec. 2020 primary colours. Primary colours for Rec. 2020 are significantly deeper than for DCI-P3, and therefore achievement of the Rec. 2020 standard for colour gamut is seen as a greater technical challenge than achieving the DCI-P3 standard.

OLED displays can successfully render the DCI-P3 colour gamut. For example, smartphones with OLED displays such as the iPhone X (Apple), Galaxy S9 (Samsung) and OnePlus 5 (OnePlus) can all render the DCI-P3 gamut. Commercial liquid crystal displays (LCDs) can also successfully render the DCI-P3 colour gamut. For example, LCDs in the Surface Studio (Microsoft), Mac Book Pro and iMac Pro (both Apple) can all render the DCI-P3 gamut. In addition, electroluminescent and photoluminescent quantum dot technology has also been used to demonstrate electroluminescent and photoluminescent QLED displays with wide colour gamut. However, until now, no display has been demonstrated that can render the Rec. 2020 colour gamut.

Here we disclose a novel stacked light emitting device architecture including one or more perovskite light emitting materials. In various embodiments, when implemented in a sub-pixel of a display, the stacked light emitting device architecture can enable the sub-pixel to render a primary colour of the DCI-P3 colour gamut. In various embodiments, when implemented in a sub-pixel of a display, the stacked light emitting device architecture can enable the sub-pixel to render a primary colour of the Rec. 2020 colour gamut.

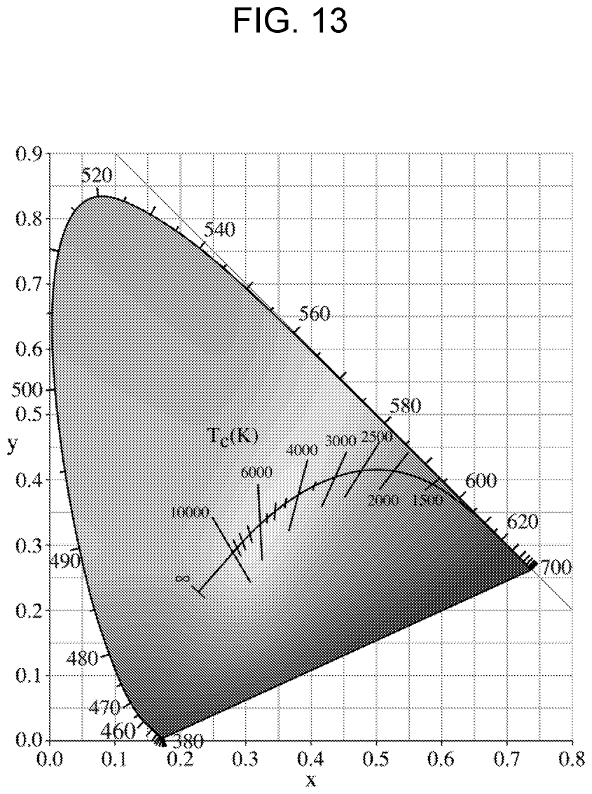

Layers, materials, regions, units and devices may be described herein in reference to the colour of light they emit. As used herein, a “white” layer, material, region, unit or device, refers to one that emits light with chromaticity coordinates that are approximately located on the Planckian Locus. The Planckian Locus is the path or locus that the colour of an incandescent blackbody would take in a particular chromaticity space as the blackbody temperature changes. FIG. 13 depicts a rendition of the CIE 1931 (x, y) color space chromaticity diagram that also shows the Planckian Locus. How closely the chromaticity of light matches the Planckian Locus can be quantified in terms of Duv=√(Δu′²+Δv′²), which is the distance in the CIE 1976 (u′, v′) color space of the light emitting device chromaticity from the Planckian Locus. The CIE 1976 (u′, v′) color space is used in preference over the CIE 1931 (x, y) color space because in the CIE 1976 (u′, v′) color space, distance is approximately proportional to perceived difference in color. The conversion is very simple: u′=4x/(−2x+12y+3) and v′=9y/(−2x+12y+3). As used herein, a “white” layer, material, region, unit or device, refers to one that emits light with CIE 1976 (u′, v′) chromaticity coordinates having Duv less than or equal to 0.010.

Further metrics that can be used to quantify “white” light include correlated colour temperature (CCT), which is the temperature of an ideal blackbody radiator that radiates light of a colour comparable to that of the light source. Preferably, a “white” light source should have CCT in the approximate range of 2700K to 6500K. More preferably, a “white” light source should have CCT in the approximate range of 3000K to 5000K.

Further metrics that can be used to quantify “white” light include colour rendering index (CRI), which is a quantitative measure of the ability of a light source to render the colours of various objects accurately in comparison with an ideal or natural light source. A higher CRI value generally corresponds to a light source being able to render colours more accurately, with 100 being the theoretical maximum value for CRI. Preferably, a “white” light source should have CRI greater than or equal to 80. More preferably, a “white” light source should have CRI greater than or equal to 90.

The advantages of stacked light emitting devices are well known in the art: light from multiple emissive units may be combined within the same surface area, thereby increasing the brightness of the device; multiple emissive units may be connected electrically in series, with substantially the same current passing through each emissive unit, thereby allowing the device to operate at increased brightness without substantial increase in current density, thereby extending the operation lifetime of the device; and the amount of light emitted from separate emissive units may be separately controlled, thereby allowing the brightness and/or colour of the device to be tuned according to the needs of the application. Connection of the emissive units in series further allows for direct current (DC) to flow through each emissive unit within the stacked light emitting device. This enables the stacked light emitting device to have a simple two electronic terminal design that is compatible with standard thin film transistor (TFT) backplane designs, such as passive matrix and active matrix backplanes used to drive electronic displays.

Examples of stacked light emitting devices that include organic light emitting materials are described in United States patent U.S. Pat. No. 5,707,745 B1, Forrest et al. and Jung et al. All of these citations are included herein by reference in their entirety. United States patent U.S. Pat. No. 5,707,745 B1 describes a multicolour stacked organic light emitting device. Forrest et al. describes a stacked organic light emitting device comprising red, green and blue emissive units that are independently addressable. Jung et al. describes a top-emitting stacked organic light emitting device with three emissive units, where light from the three emissive units may be combined to generate emission of white light from the device.

Although the performance advantages of stacked light emitting devices are known in relation to organic light emitting material, until now, no stacked light emitting device has been demonstrated that comprises perovskite light emitting material. We demonstrate that various additional performance advantages can be realized by including at least one perovskite light emitting material in one or more emissive units of a stacked light emitting device.

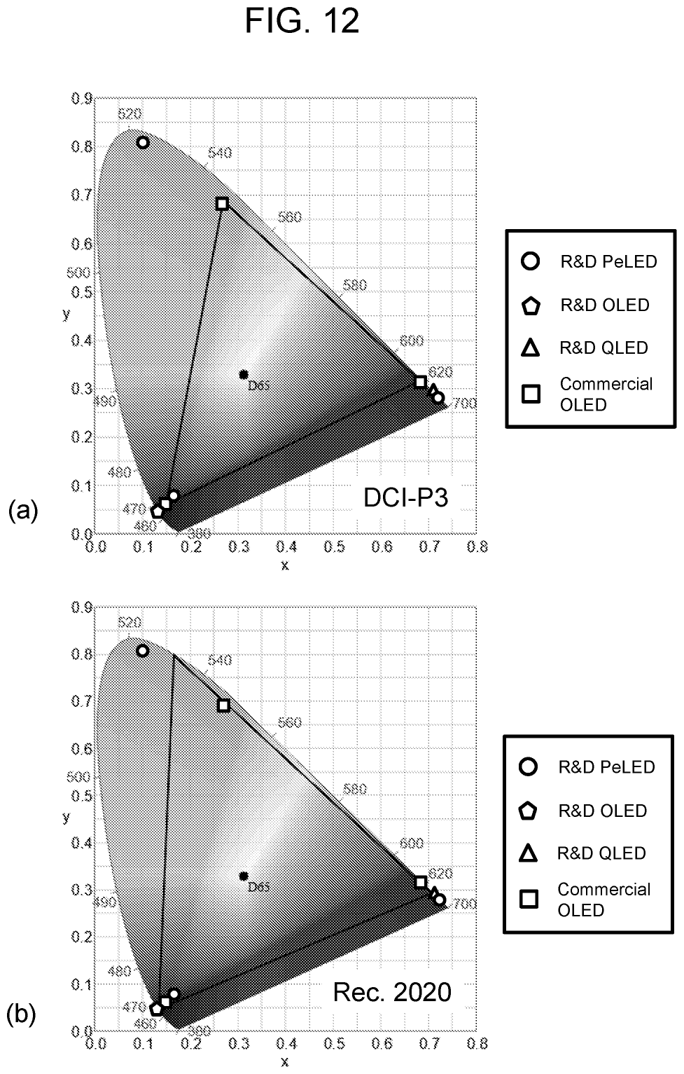

One or more advantages of including at least one perovskite light emitting material in at least one emissive unit of a stacked light emitting device may be demonstrated using the data shown in Table 1 and FIG. 12. The data in Table 1 and FIG. 12 may also be used to demonstrate one or more advantages of combining one or more emissive units including perovskite light emitting material with one or more emissive units including organic light emitting material and/or quantum dot light emitting material in a stacked light emitting device architecture.

Table 1 shows CIE 1931 (x, y) colour coordinates for single emissive unit red, green and blue PeLED, OLED and QLED devices. Also included in Table 1 are CIE 1931 (x, y) colour coordinates for DCI-P3 and Rec. 2020 colour gamut standards. Generally, for red light, a higher CIE×value corresponds to deeper emission colour, for green light, a higher CIE y value corresponds to deeper emission colour, and for blue light, a lower CIE y value corresponds to deeper emission colour. This can be understood with reference FIG. 12, which includes markers for the red, green and blue R&D PeLED (circles), blue R&D OLED (pentagon), red R&D QLED (triangles) and Commercial OLED (squares) device data in Table 1, as well as markers for the primary colours of the DCI-P3 colour gamut in FIG. 12a and for the Rec. 2020 colour gamut in FIG. 12b.

TABLE 1
CIE 1931 (x, y) colour coordinates for exemplary single emissive
unit PeLED, OLED and QLED devices. Also included are colour
coordinates for DCI-P3 and Rec. 2020 colour gamut standards.

| | Red | | Green | | Blue | |
|---|---|---|---|---|---|---|
| | CIE x | CIE y | CIE x | CIE y | CIE x | CIE y |
| DCI-P3 | 0.680 | 0.320 | 0.265 | 0.690 | 0.150 | 0.060 |
| Rec. 2020 | 0.708 | 0.292 | 0.170 | 0.797 | 0.131 | 0.046 |
| Commercial OLED | 0.680 | 0.320 | 0.265 | 0.690 | 0.150 | 0.060 |
| R&D PeLED | 0.720 | 0.280 | 0.100 | 0.810 | 0.166 | 0.079 |
| R&D OLED | — | — | — | — | 0.146 | 0.045 |
| R&D QLED | 0.712 | 0.288 | — | — | — | — |

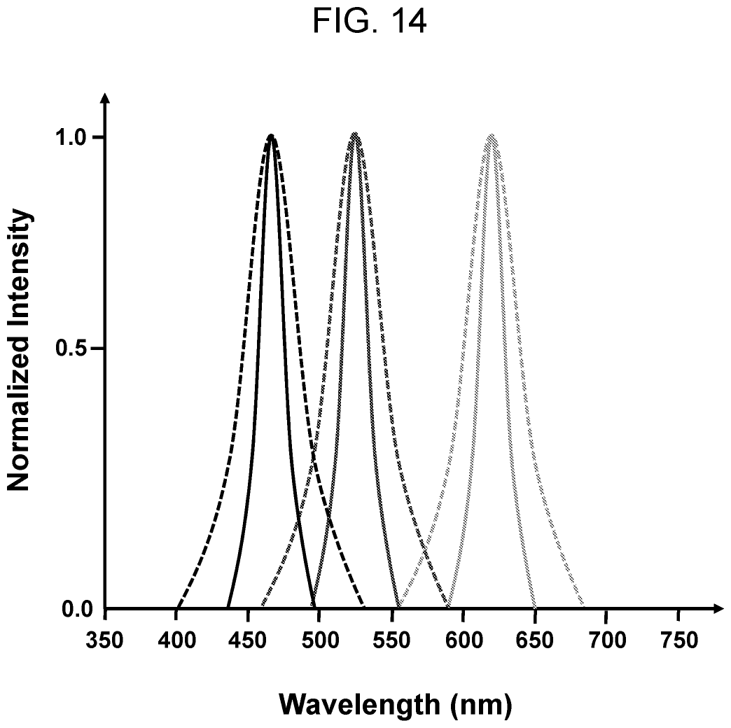

FIG. 14 depicts exemplary electroluminescence emission spectra for single emissive unit red, green and blue PeLEDs, OLEDs and QLEDs. The red, green and blue spectra depicted using dashed lines correspond to spectra for Commercial OLED devices, such as those in the Apple iPhone X, which may be used to render the DCI-P3 colour gamut. The red spectrum depicted using a solid line corresponds to the spectrum for a red light emitting R&D PeLED device with a single emissive unit. The green spectrum depicted using a solid line corresponds to the spectrum for a green light emitting R&D PeLED device with a single emissive unit. The blue spectrum depicted using a solid line corresponds to the spectrum for a blue light emitting R&D OLED device with a single emissive unit. It can be seen from FIG. 14 that as an emission spectrum narrows, emission colour becomes more saturated. Electroluminescence spectra depicted using solid lines in FIG. 14 correspond to light emitting devices that may be used to render the Rec. 2020 colour gamut.

The CIE 1931 (x, y) colour coordinate data reported for single emissive unit red, green and blue PeLED, OLED and QLED devices in Table 1 are exemplary. Commercial OLED data are taken from the Apple iPhone X, which fully supports the DCI-P3 colour gamut. This data set is available from Raymond Soneira at DisplayMate Technologies Corporation (Soneira et al.). Data for R&D PeLED, R&D OLED and R&D QLED devices are taken from a selection of peer-reviewed scientific journals: Red R&D PeLED data are taken from Wang et al. Red R&D QLED data are taken from Kathirgamanathan et al. (2). Green R&D PeLED data are taken from Hirose et al. Blue R&D PeLED data are taken from Kumar et al. Blue R&D OLED data are taken from Takita et al. Data from these sources are used by way of example, and should be considered non-limiting. Data from other peer-reviewed scientific journals, simulated data and/or experimental data collected from laboratory devices may also be used to demonstrate the aforementioned advantages of the claimed stacked light emitting device architecture.

As can be seen from Table 1 and FIG. 12a, existing organic light emitting materials and devices can already be used to demonstrate a commercial display that can render the DCI-P3 colour gamut, as is exemplified by the Apple iPhone X. However, as can be seen from FIG. 12b, existing organic light emitting materials and devices alone cannot be used to demonstrate a display that can render the Rec. 2020 colour gamut. Table 1 and FIG. 12b show that one path to demonstrating a display that can render the Rec. 2020 colour gamut is to include one or more perovskite light emitting materials in one or light emitting devices in one or more sub-pixels of a display.

However, colour gamut is only one metric by which the performance of a display may be measured. Other parameters, such as efficiency, brightness, operational lifetime, voltage, process conditions and cost must also be considered in the design of light emitting devices for application in a display. Notably, at this early stage in their development, operational lifetimes for perovskite light emitting materials are relatively short. For example, all operational lifetimes previously reported for single emissive unit device architectures with perovskite light emitting materials are insufficient to fulfill requirements for application in commercial displays and light panels.

In this invention, we propose a stacked light emitting device architecture with multiple emissive units, wherein at least one emissive units comprises a perovskite light emitting material. By stacking multiple emissive units in a light emitting device, substantially the same current may pass through each emissive unit, thereby allowing the device to operate at increased brightness without substantial increase in current density, thereby extending the operation lifetime of the device.

Generally, the operational lifetime (LT) of a PeLED, OLED or QLED at luminance (L) may be expressed as LT₂=LT₁×(Li/L₂)^{AF} where LT₁ is the measured lifetime of the device at high luminance L₁, LT₂ is the predicted lifetime at (low) luminance L₂ and AF is the acceleration factor. Approximate acceleration factors to convert measured lifetimes at higher luminance to predicted lifetimes at lower luminance have been determined to be in the approximate range of 1.5-2.0 for PeLEDs, OLEDs and QLEDs.

For a stacked light emitting device comprising two emissive units, for the same total device luminance each emissive unit may operate with luminance L₂ that is two times lower than the luminance L₁ required for an equivalent light emitting device with a single emissive unit. If an acceleration factor of 2.0 is assumed, then the expected operational lifetime for a stacked light emitting device with two emissive units is 2²=4 times longer than that of an equivalent light emitting device with a single emissive unit. Furthermore, for a stacked light emitting device comprising three emissive units, for the same total device luminance each emissive unit may operate with luminance L₂ that is three times lower than the luminance L₁ required for an equivalent light emitting device with a single emissive unit. If an acceleration factor of 2.0 is assumed, then the expected operational lifetime for a stacked light emitting device with three emissive units is 3²=9 times longer than that of an equivalent light emitting device with a single emissive unit. The approach of using a stacked light emitting device architecture may therefore accelerate the adoption of perovskite light emitting materials in commercial displays and light panels.

Optionally, by including one or more perovskite light emitting materials in a stacked light emitting device, the device may emit green light with CIE 1931 (x, y)=(0.100, 0.810), which as can be seen from FIG. 12b, is more saturated than the green primary colour for the Rec. 2020 standard, which has CIE 1931 (x, y)=(0.170, 0.797). Optionally, chromaticity more saturated than the green primary colour of the Rec. 2020 standard may be demonstrated using a stacked light emitting device comprising a first emissive unit and a second emissive unit, wherein the first emissive unit comprises a perovskite green light emitting material, and the second emissive unit comprises a perovskite green light emitting material. Optionally, chromaticity more saturated than the green primary colour of the Rec. 2020 standard may be demonstrated using a stacked light emitting device comprising a first emissive unit, a second emissive unit and a third emissive unit, wherein the first emissive unit comprises a perovskite green light emitting material, the second emissive unit comprises a perovskite green light emitting material, and the third emissive unit comprises a perovskite green light emitting material.

Optionally, by including one or more perovskite light emitting materials in a stacked light emitting device, one or more emissive units of the device may emit red light with CIE 1931 (x, y)=(0.720, 0.280), which as can be seen from FIG. 12b, is more saturated than the red primary color for the Rec. 2020 standard, which has CIE 1931 (x, y)=(0.708, 0.292). Optionally, chromaticity more saturated than the red primary colour of the Rec. 2020 standard may be demonstrated using a stacked light emitting device comprising a first emissive unit and a second emissive unit, wherein the first emissive unit comprises a perovskite red light emitting material, and the second emissive unit comprises a perovskite red light emitting material. Optionally, chromaticity more saturated than the red primary colour of the Rec. 2020 standard may be demonstrated using a stacked light emitting device comprising a first emissive unit, a second emissive unit and a third emissive unit, wherein the first emissive unit comprises a perovskite red light emitting material, the second emissive unit comprises a perovskite red light emitting material, and the third emissive unit comprises a perovskite red light emitting material.

Furthermore, in this invention, we propose that it may be advantageous under some circumstances to combine one or more emissive units comprising perovskite light emitting material with one or more emissive units comprising quantum dot light emitting material in a stacked light emitting device architecture.

Optionally, by including one or more quantum dot light emitting materials in a stacked light emitting device, one or more emissive units of the device may emit red light with CIE 1931 (x, y)=(0.712, 0.288), which as can be seen from FIG. 12b, is more saturated than the red primary color for the Rec. 2020 standard, which has CIE 1931 (x, y)=(0.708, 0.292). As described herein, the colour saturation of red light emission from exemplary emissive units comprising quantum dot light emitting material may be slightly less than that of red light emission from exemplary emissive units comprising perovskite light emitting material. However, under some circumstances, including quantum dot red light emitting material may provide the device with one or more advantages, such as improved efficiency, higher brightness, improved operational lifetime, lower voltage and/or reduced cost, and may therefore be preferred for implementation in a stacked light emitting device architecture.

Optionally, chromaticity more saturated than the red primary colour of the Rec. 2020 standard may be demonstrated using a stacked light emitting device comprising a first emissive unit and a second emissive unit, wherein at least one emissive unit comprises a perovskite red light emitting material, and at least one emissive unit comprises a quantum dot red light emitting material. Optionally, chromaticity more saturated than the red primary colour of the Rec. 2020 standard may be demonstrated using a stacked light emitting device comprising a first emissive unit, a second emissive unit and a third emissive unit, wherein at least one emissive unit comprises a perovskite red light emitting material, and at least one emissive unit comprises quantum dot red light emitting material.

Furthermore, in this invention, we propose that it may be advantageous under some circumstances to combine one or more emissive units comprising perovskite light emitting material with one or more emissive units comprising organic light emitting material in a stacked light emitting device architecture.

Optionally, by including one or more organic light emitting materials in a stacked light emitting device, one or more emissive units of the device may emit blue light with CIE 1931 (x, y)=(0.146, 0.045), which as can be seen from FIG. 12b, is more saturated than the blue primary color for the Rec. 2020 standard, which has CIE 1931 (x, y)=(0.131, 0.046).

Optionally, chromaticity more saturated than the blue primary colour of the Rec. 2020 standard may be demonstrated using a stacked light emitting device comprising a first emissive unit and a second emissive unit, wherein at least one emissive unit comprises a perovskite blue light emitting material, and at least one emissive unit comprises an organic blue light emitting material. Optionally, chromaticity more saturated than the blue primary colour of the Rec. 2020 standard may be demonstrated using a stacked light emitting device comprising a first emissive unit, a second emissive unit and a third emissive unit, wherein at least one emissive unit comprises a perovskite blue light emitting material, and at least one emissive unit comprises an organic blue light emitting material.

As described herein, the colour saturation of blue light emission from exemplary emissive units comprising perovskite blue light emitting material may be slightly less than that of blue light emission from exemplary emissive units comprising organic blue light emitting material. For example, as shown in Table 1, a perovskite blue light emitting material may emit light with CIE 1931 (x, y)=(0.166, 0.079), which as can be seen from FIG. 12b, is less saturated than the blue primary color for the Rec. 2020 standard, which has CIE 1931 (x, y)=(0.131, 0.046). However, under some circumstances, including perovskite blue light emitting material may provide the device with one or more advantages, such as improved efficiency, higher brightness, improved operational lifetime, lower voltage and/or reduced cost, and may therefore be preferred for implementation in a stacked light emitting device architecture. With the correct combination of light emission from an emissive unit comprising perovskite blue light emitting material and an emissive unit comprising organic blue light emitting material, a stacked light emitting device may emit blue light with chromaticity more saturated that the blue primary colour of the Rec. 2020 standard, while maintaining the advantages of including blue perovskite light emitting material.

Optionally, by combining one or more emissive units comprising one or more perovskite light emitting materials with one or more emissive units comprising one or more organic light emitting materials and/or one or more quantum dot light emitting materials, a stacked light emitting device that may render a primary colour of the DCI-P3 colour gamut may be demonstrated. In one embodiment, the stacked light emitting device may emit red light with CIE 1931×coordinate greater than or equal to 0.680. In one embodiment, the stacked light emitting device may emit green light with CIE 1931 y coordinate greater than or equal to 0.690. In one embodiment, the stacked light emitting device may emit blue light with CIE 1931 y coordinate less than or equal to 0.060. Such a device may be of advantage in that it fulfills colour gamut requirements of the DCI-P3 display standard. Such a device may be of advantage in that when implemented in one or more sub-pixels of a display, the display may render a broader range of colours experienced in everyday life, thereby improving functionality and user experience.

Optionally, by combining one or more emissive units comprising one or more perovskite light emitting materials with one or more emissive units comprising one or more organic light emitting materials and/or one or more quantum dot light emitting materials, a stacked light emitting device that may render a primary colour of the Rec. 2020 colour gamut may be demonstrated. In one embodiment, the stacked light emitting device may emit red light with CIE 1931×coordinate greater than or equal to 0.708. In one embodiment, the stacked light emitting device may emit green light with CIE 1931 y coordinate greater than or equal to 0.797. In one embodiment, the stacked light emitting device may emit blue light with CIE 1931 y coordinate less than or equal to 0.046. Such a device may be of advantage in that it fulfills colour gamut requirements of the Rec. 2020 display standard. Such a device may be of advantage in that when implemented in one or more sub-pixels of a display, the display may render a broader range of colours experienced in everyday life, thereby improving functionality and user experience.

Optionally, by including one or more perovskite light emitting materials in a stacked light emitting device, the device may emit white light. Optionally, white light emission may be demonstrated using a stacked light emitting device comprising a first emissive unit and a second emissive unit, wherein at least one emissive unit comprises a yellow light emitting material, and at least one emissive unit comprises a blue light emitting material. White light emission may be demonstrated by combining yellow and blue light emission from the respective emissive units.

Optionally, the yellow light emitting material may be a perovskite light emitting material, and the blue light emitting material may be a perovskite light emitting material, an organic light emitting material or a quantum dot light emitting material. Optionally, the yellow light emitting material may be a perovskite light emitting material, an organic light emitting material or a quantum dot light emitting material, and the blue light emitting material may be a perovskite light emitting material. Optionally, the yellow light emitting material may be a perovskite light emitting material and the blue light emitting material may be a perovskite light emitting material. Optionally, the yellow light emitting material may be a perovskite light emitting material and the blue light emitting material may be an organic light emitting material. The inclusion of an organic blue light emitting material may be preferred because such a material may enable the device to demonstrate longer operational lifetime.

Optionally, white light emission may be demonstrated using a stacked light emitting device comprising a first emissive unit, a second emissive unit and a third emissive unit, wherein at least one emissive unit comprises a red light emitting material, at least one emissive unit comprises a green light emitting material, and at least one emissive unit comprises a blue light emitting material. White light emission may be demonstrated by combining red, green and blue light emission from the respective emissive units.

Optionally, the red light emitting material may be a perovskite light emitting material, the green light emitting material may be a perovskite light emitting material, an organic light emitting material or a quantum dot light emitting material, and the blue light emitting material may be a perovskite light emitting material, an organic light emitting material or a quantum dot light emitting material. Optionally, the red light emitting material may be a perovskite light emitting material, an organic light emitting material or a quantum dot light emitting material, the green light emitting material may be a perovskite light emitting material, and the blue light emitting material may be a perovskite light emitting material, an organic light emitting material or a quantum dot light emitting material. Optionally, the red light emitting material may be a perovskite light emitting material, an organic light emitting material or a quantum dot light emitting material, the green light emitting material may be a perovskite light emitting material, an organic light emitting material or a quantum dot light emitting material, and the blue light emitting material may be a perovskite light emitting material. Optionally, the red light emitting material may be a perovskite light emitting material, the green light emitting material may be a perovskite light emitting material and the blue light emitting material may be a perovskite light emitting material. Optionally, the red light emitting material may be a perovskite light emitting material, the green light emitting material may be a perovskite light emitting material and the blue light emitting material may be an organic light emitting material. The inclusion of an organic blue light emitting material may be preferred because such a material may enable the device to demonstrate longer operational lifetime.

Such stacked white light emitting devices comprising one or more perovskite light emitting materials may be advantageous because the higher colour saturation of perovskite light emitting materials may enable white light emission with higher colour rendering index (CRI) than for equivalent devices comprising only organic light emitting material and/or quantum dot light emitting material. This may be advantageous for application in a light panel.

Such stacked white light emitting devices comprising one or more perovskite light emitting materials may be advantageous because the higher colour saturation of perovskite light emitting materials may enable the device to be optically coupled to one or more colour altering layers more efficiently than for equivalent devices comprising only organic light emitting material and/or quantum dot light emitting material. This may be advantageous for application in a display.

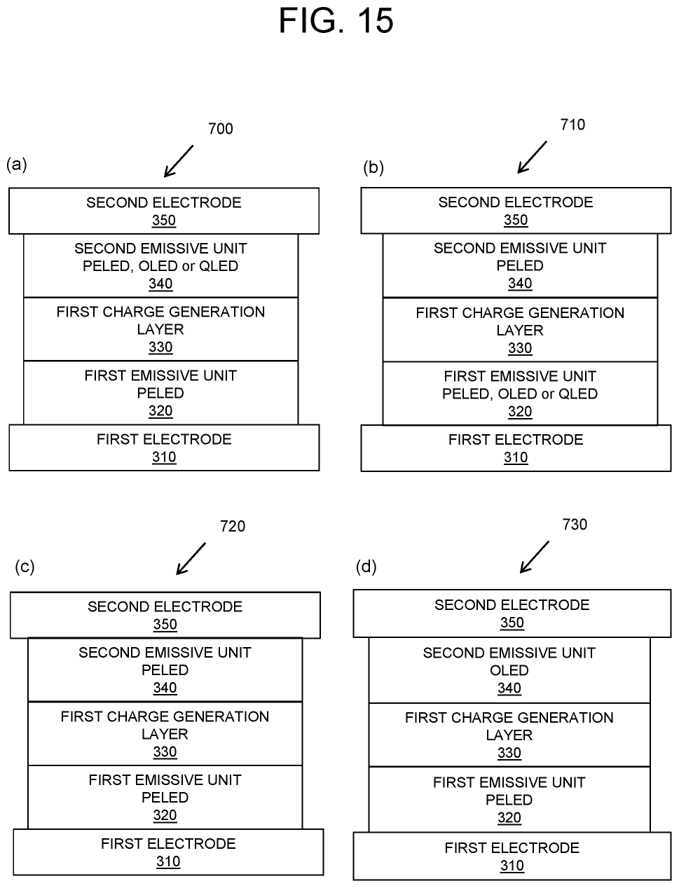

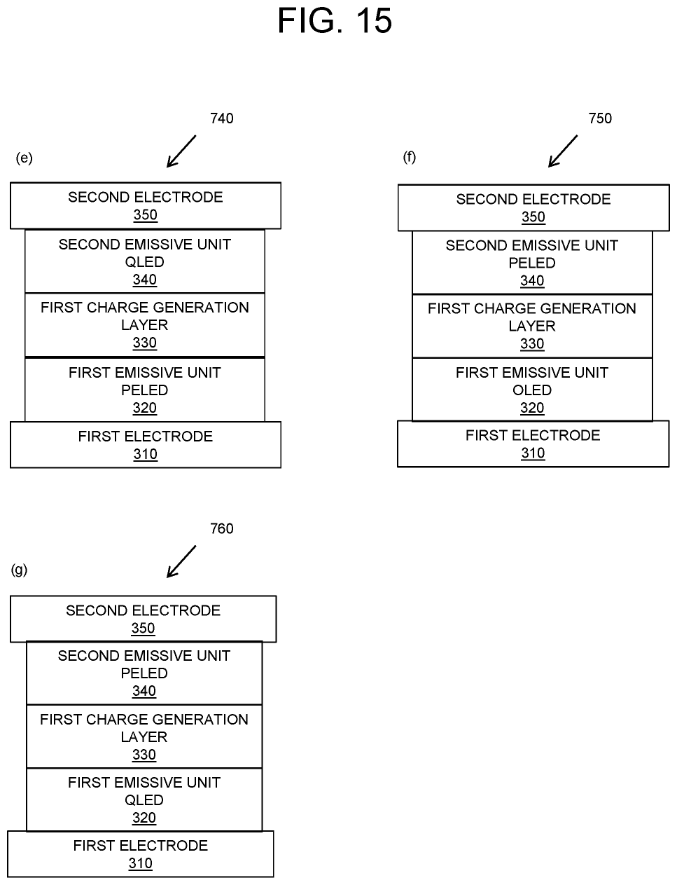

FIG. 15 depicts various configurations of emissive units for a stacked light emitting device having two emissive units. In each configuration, the stacked light emitting device comprises a first electrode 310, a first emissive unit 320, a first charge generation layer 330, a second emissive unit 340 and a second electrode 350. The first emissive unit 320, the first charge generation layer 330 and the second emissive unit 340 are disposed between the first electrode 310 and the second electrode 350. The first emissive unit 320 is disposed over the first electrode 310. The first charge generation layer 330 is disposed over the first emissive unit 320. The second emissive unit 340 is disposed over the first charge generation layer 330. The second electrode 350 is disposed over the second emissive unit 340. In each configuration, the stacked light emitting device comprises at least one emissive unit that comprises perovskite light emitting material, and at least one further emissive unit that comprises perovskite light emitting material, organic light emitting material or quantum dot light emitting material. Such a stacked light emitting device architecture may be advantageous because the combination of different light emitting materials may enable the optimum type of light emitting material to be selected for each emissive unit, thereby enhancing performance beyond that which could be achieved by a stacked light emitting device comprising only a single type of light emitting material, such as only perovskite light emitting material, only organic light emitting material or only quantum dot light emitting material. For example, the colour gamut, electroluminescence efficiency and/or electroluminescence stability of the device may be enhanced.

For simplicity, in FIGS. 15, 16 and 17, an emissive unit comprising perovskite light emitting material is labelled “PELED”, an emissive unit comprising organic light emitting material is labelled “OLED”, and an emissive unit comprising quantum dot light emitting material is labelled “QLED”. An emissive unit comprising perovskite light emitting material, organic light emitting material or quantum dot light emitting material is labelled “PeLED, OLED or QLED”.

In one embodiment, the first emissive unit 320 may comprise a perovskite light emitting material, and the second emissive unit 340 may comprise a perovskite light emitting material, an organic light emitting material or a quantum dot light emitting material. This embodiment is depicted by stacked light emitting device 700 in FIG. 15a.

In one embodiment, the first emissive unit 320 may comprise a perovskite light emitting material, an organic light emitting material or quantum dot light emitting material, and the second emissive unit 340 may comprise a perovskite light emitting material. This embodiment is depicted by stacked light emitting device 710 in FIG. 15b.

In one embodiment, the at least one further emissive unit may comprises a perovskite light emitting material or an organic light emitting material. This embodiment is depicted by stacked light emitting devices 720 in FIG. 15c, 730 in FIGS. 15d and 750 in FIG. 15f.

In one embodiment, the first emissive unit 320 may comprise a perovskite light emitting material, and the second emissive unit 340 may comprise a perovskite light emitting material. This embodiment is depicted by stacked light emitting device 720 in FIG. 15c. Such a device architecture may be advantageous in that the manufacturing process may be simplified for a stacked light emitting device comprising only PeLED emissive units.

In one embodiment, the at least one further emissive unit may comprise an organic light emitting material. This embodiment is depicted by stacked light emitting devices 730 in FIGS. 15d and 750 in FIG. 15f. Such device architectures may be advantageous because a perovskite light emitting material may be preferred for at least one emissive unit of a stacked light emitting device, but the performance of the device may be enhanced if an organic light emitting material is used for a further emissive unit of the device. For example, the colour gamut, electroluminescence efficiency and/or electroluminescence stability of the device may be enhanced. Combination of PeLED emissive units with OLED emissive units within a stacked light emitting device may be particularly advantageous because organic light emitting materials with commercial performance may be complemented and enhanced by perovskite light emitting material performance.

In one embodiment, the first emissive unit 320 may comprise a perovskite light emitting material, and the second emissive unit 340 may comprise an organic light emitting material. This embodiment is depicted by stacked light emitting device 730 in FIG. 15d.

In one embodiment, the first emissive unit 320 may comprise an organic light emitting material, and the second emissive unit 340 may comprise a perovskite light emitting material. This embodiment is depicted by stacked light emitting device 750 in FIG. 15f.

In one embodiment, the at least one further emissive unit may comprises a perovskite light emitting material or a quantum dot light emitting material. This embodiment is depicted by stacked light emitting devices 720 in FIG. 15c, 740 in FIGS. 15e and 760 in FIG. 15g.

In one embodiment, the first emissive unit 320 may comprise a perovskite light emitting material, and the second emissive unit 340 may comprise a perovskite light emitting material. This embodiment is depicted by stacked light emitting device 720 in FIG. 15c. Such a device architecture may be advantageous in that the manufacturing process may be simplified for a stacked light emitting device comprising only PeLED emissive units.

In one embodiment, the at least one further emissive unit may comprise a quantum dot light emitting material. This embodiment is depicted by exemplary stacked light emitting devices 740 in FIGS. 15e and 760 in FIG. 15g. Such device architectures may be advantageous because a perovskite light emitting material may be preferred for at least one emissive unit of a stacked light emitting device, but the performance of the device may be enhanced if a quantum dot light emitting material is used for a further emissive unit of the device. For example, the colour gamut, electroluminescence efficiency and/or electroluminescence stability of the device may be enhanced. Combination of PeLED emissive units with QLED emissive units within a stacked light emitting device may be particularly advantageous because the similarity of structure of perovskite light-emitting materials and quantum dot light-emitting materials may allow these emissive units to be manufactured together with little or no added complexity. For example, in the case of solution-process manufacturing, common solvents may be used to process perovskite light-emitting materials and quantum dot light-emitting materials.

In one embodiment, the first emissive unit 320 may comprise a perovskite light emitting material, and the second emissive unit 340 may comprise a quantum dot light emitting material. This embodiment is depicted by stacked light emitting device 740 in FIG. 15e.

In one embodiment, the first emissive unit 320 may comprise a quantum dot light emitting material, and the second emissive unit 340 may comprise a perovskite light emitting material. This embodiment is depicted by stacked light emitting device 760 in FIG. 15g.

In one embodiment, each emissive unit of the stacked light emitting device may comprise one, and not more than one, emissive layer. In one embodiment, each emissive unit of the stacked light emitting device may comprise one, and not more than one, light emitting material. Such light emitting devices may be advantageous in that they may enable emission of highly saturated light. Such light emitting devices may also be of advantage in that they may simplify the production process.

In one embodiment, the stacked light emitting device may include a microcavity structure. Optionally, as described herein, a microcavity structure may be created where a transparent and partially reflective electrode is used in combination with an opposing reflective electrode. Optionally, in a standard device architecture, a bottom-emission microcavity structure may be created using a transparent and partially reflective multilayer anode such as ITO/Ag/ITO, where the Ag thickness is less than approximately 25 nm, in combination with a reflective multilayer cathode such as LiF/Al. In this architecture, light emission is through the anode. Optionally, in a standard device architecture, a top-emission microcavity structure may be created using a transparent and partially reflective compound cathode such as Mg:Ag in combination with a reflective multilayer anode such as ITO/Ag/ITO, where the Ag thickness is greater than approximately 80 nm. In this architecture, light emission is through the cathode.

Such a device may be of advantage in that such a microcavity structure may increase the total amount of light emitted from the device, thereby increasing the efficiency and brightness of the device. Such a device may further be of advantage in that such a microcavity structure may increase the proportion of light emitted in the forward direction from the device, thereby increasing the apparent brightness of the device to a user positioned at normal incidence. Such a device may further be of advantage in that such a microcavity structure may narrow the spectrum of emitted light from the device, thereby increasing the colour saturation of the emitted light. Application of such a microcavity structure to the device may thereby enable the device to render a primary colour of the DCI-P3 colour gamut. Application of such a microcavity structure to the device may thereby enable the device to render a primary colour of the Rec. 2020 colour gamut.

In one embodiment, the stacked light emitting device may emit red light. In one embodiment the stacked light emitting device may emit red light that is capable of rendering the red primary colour of the DCI-P3 colour gamut. In one embodiment, the stacked light emitting device may emit red light with CIE 1931×coordinate greater than or equal to 0.680. In one embodiment the stacked light emitting device may emit red light that is capable of rendering the red primary colour of the Rec. 2020 colour gamut. In one embodiment, the stacked light emitting device may emit red light with CIE 1931×coordinate greater than or equal to 0.708. As depicted in Table 1, this depth of colour may be achieved using one or more perovskite light emitting materials and/or one or more quantum dot light emitting materials. When implemented in a sub-pixel of a display, such a device may enable the display to render a broader range of colours.

In one embodiment, the stacked light emitting device may emit green light. In one embodiment the stacked light emitting device may emit green light that is capable of rendering the green primary colour of the DCI-P3 colour gamut. In one embodiment, the stacked light emitting device may emit green light with CIE 1931 y coordinate greater than or equal to 0.690. In one embodiment the stacked light emitting device may emit green light that is capable of rendering the green primary colour of the Rec. 2020 colour gamut. In one embodiment, the stacked light emitting device may emit green light with CIE 1931 y coordinate greater than or equal to 0.797. As depicted in Table 1, this depth of colour may be achieved using one or more perovskite light emitting materials. When implemented in a sub-pixel of a display, such a device may enable the display to render a broader range of colours.

In one embodiment, the tacked light emitting device may emit blue light. In one embodiment the stacked light emitting device may emit blue light that is capable of rendering the blue primary colour of the DCI-P3 colour gamut. In one embodiment, the stacked light emitting device may emit blue light with CIE 1931 y coordinate less than or equal to 0.060. In one embodiment the stacked light emitting device may emit blue light that is capable of rendering the blue primary colour of the Rec. 2020 colour gamut. In one embodiment, the stacked light emitting device may emit blue light with CIE 1931 y coordinate less than or equal to 0.046. As depicted in Table 1, this depth of colour may be achieved using one or more organic light emitting materials. When implemented in a sub-pixel of display, such a device may enable the display to render a broader range of colours.

In one embodiment, the stacked light emitting device may emit white light. In one embodiment, the stacked light emitting device may be incorporated into a light panel. In one embodiment, the stacked light emitting device may emit white light having Duv less than or equal to 0.010. In one embodiment, the stacked light emitting device may emit white light having Duv less than or equal to 0.005. Having a small Duv value may be of advantage in that the light emitting device may closely resemble a blackbody radiator. In one embodiment, the stacked light emitting device may emit white light with CCT in the range of approximately 2700K to 6500K. In one embodiment, the stacked light emitting device may emit light with CCT in the range of approximately 3000K to 5000K. Having a CCT in this range may be of advantage in that the light emitting device may appear a more natural colour and may meet the United States Department of Energy standard for Energy Star certification for Solid State Lighting. In one embodiment, the stacked light emitting device may emit white light such that the CRI of the light emitting device is greater than or equal to 80. In one embodiment, the stacked light emitting device may emit white light such that the CRI of the light emitting device is greater than or equal to 90. Having a high CRI may be of advantage in that the light emitting device may be able to render colours more accurately.

In one embodiment, the stacked light emitting device may be incorporated into a sub-pixel of a display. In one embodiment, the stacked light emitting device may emit white light with CCT of approximately 6504K. Having a CCT of approximately 6504K may be of advantage in that the display may be easily calibrated to the illuminant D65 white point, which is the white point used for both DCI-P3 and Rec. 2020 standards.

In one embodiment, the stacked light emitting device may be included in a sub-pixel of a display. Optionally, the display may be incorporated into a wide range of consumer products. Optionally, the display may be used in televisions, computer monitors, tablets, laptop computers, smart phones, cell phones, digital cameras, video recorders, smartwatches, fitness trackers, personal digital assistants, vehicle displays and other electronic devices. Optionally, the display may be used for micro-displays or heads-up displays. Optionally, the display may be used in light sources for interior or exterior illumination and/or signaling, in smart packaging or in billboards.

In one embodiment, the stacked light emitting device may be included in a light panel. Optionally, the light panel may be included in a wide range of consumer products. Optionally the light panel may be used for interior or exterior illumination and/or signaling, in smart packaging or in billboards.

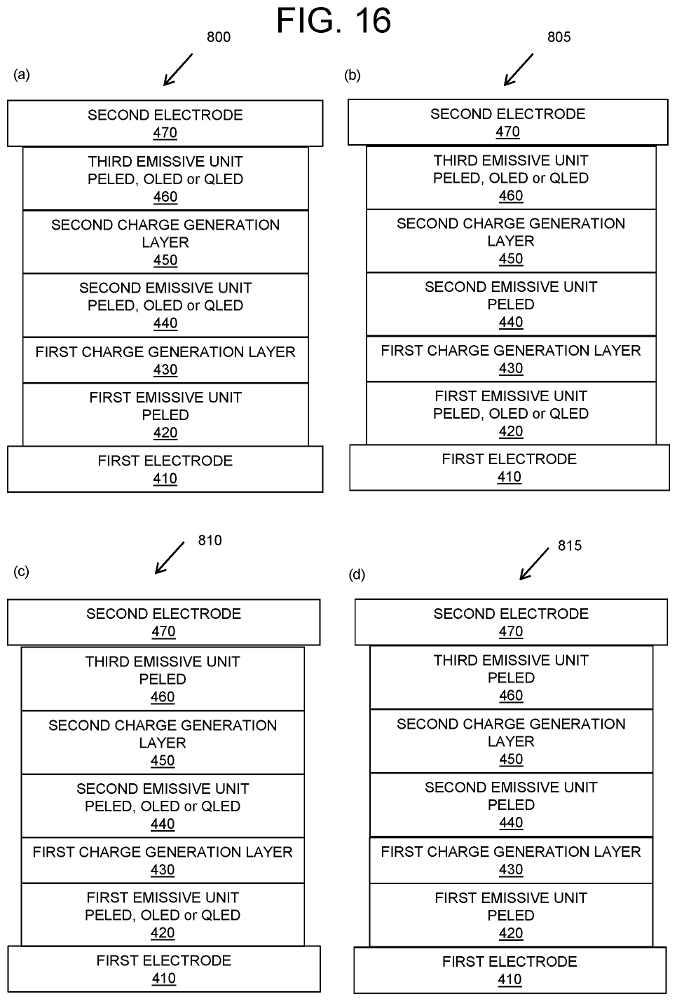

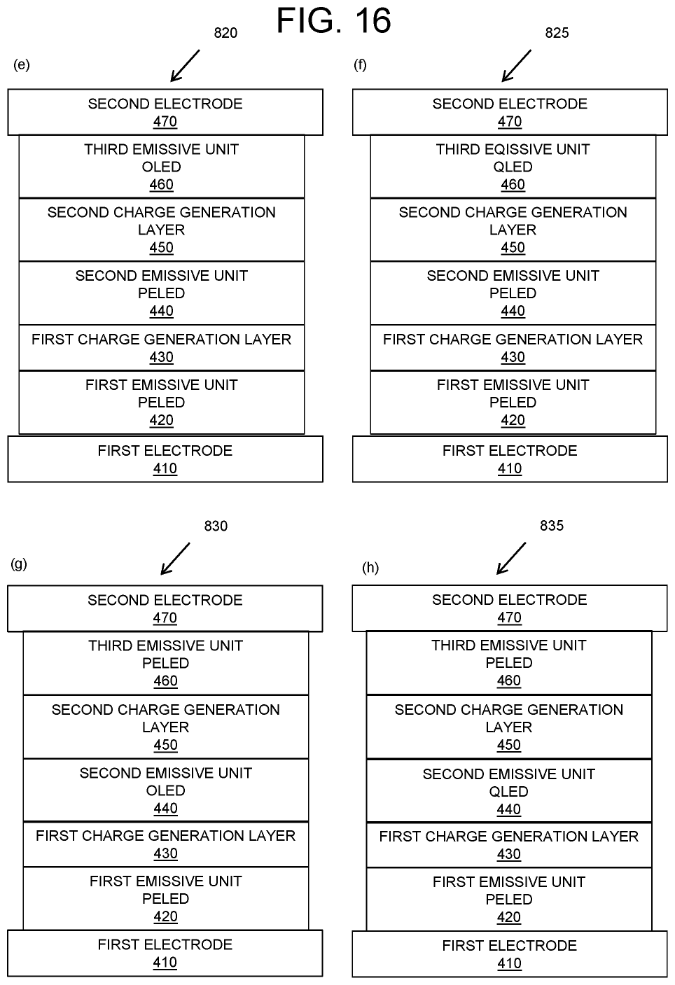

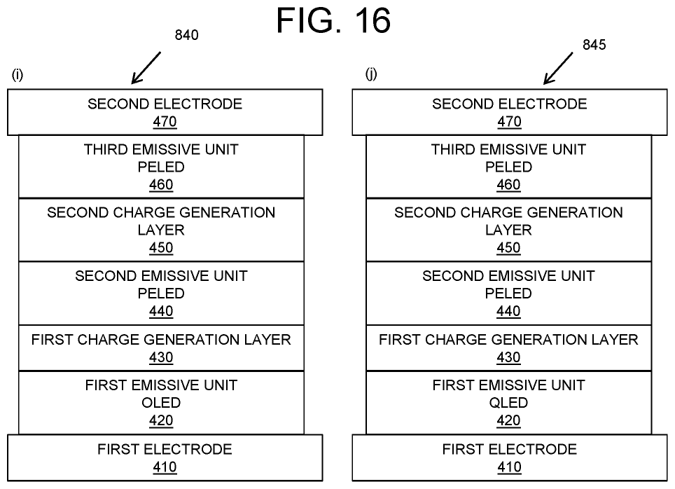

FIG. 16 depicts various configurations of emissive units for a stacked light emitting device having three emissive units. In each configuration, the stacked light emitting device comprises a first electrode 410, a first emissive unit 420, a first charge generation layer 430, a second emissive unit 440, a second charge generation layer 450, a third emissive unit 460, and a second electrode 470. The first emissive unit 420, the first charge generation layer 430, the second emissive unit 440, the second charge generation layer 450 and the third emissive unit 460 are disposed between the first electrode 410 and the second electrode 470. The first emissive unit 420 is disposed over the first electrode 410. The first charge generation layer 430 is disposed over the first emissive unit 420. The second emissive unit 440 is disposed over the first charge generation layer 430. The second charge generation layer 450 is disposed over the second emissive unit 440. The third emissive unit 460 is disposed over the second charge generation layer 450. The second electrode 470 is disposed over the third emissive unit 460. In each configuration, the stacked light emitting device comprises at least one emissive unit that comprises perovskite light emitting material, and at least two further emissive units that each comprise perovskite light emitting material, organic light emitting material or quantum dot light emitting material. Such a stacked light emitting device architecture may be advantageous because the combination of different light emitting materials may enable the optimum type of light emitting material to be selected for each emissive unit, thereby enhancing performance beyond that which could be achieved by a stacked light emitting device comprising only a single type of light emitting material, such as only perovskite light emitting material, only organic light emitting material or only quantum dot light emitting material. For example, the colour gamut, electroluminescence efficiency and/or electroluminescence stability of the device may be enhanced.

In one embodiment, the first emissive unit 420 may comprise a perovskite light emitting material, the second emissive unit 440 may comprise a perovskite light emitting material, an organic light emitting material or a quantum dot light emitting material, and the third emissive unit 460 may comprise a perovskite light emitting material, an organic light emitting material or a quantum dot light emitting material. This embodiment is depicted by stacked light emitting device 800 in FIG. 16a.

In one embodiment, the first emissive unit 420 may comprise a perovskite light emitting material, an organic light emitting material or a quantum dot light emitting material, the second emissive unit 440 may comprise a perovskite light emitting material, and the third emissive unit 460 may comprise a perovskite light emitting material, an organic light emitting material or a quantum dot light emitting material. This embodiment is depicted by stacked light emitting device 805 in FIG. 16b.

In one embodiment, the first emissive unit 420 may comprise a perovskite light emitting material, an organic light emitting material or a quantum dot light emitting material, the second emissive unit 440 may comprise a perovskite light emitting material, an organic light emitting material or a quantum dot light emitting material, and the third emissive unit 460 may comprise a perovskite light emitting material. This embodiment is depicted by stacked light emitting device 810 in FIG. 16c.

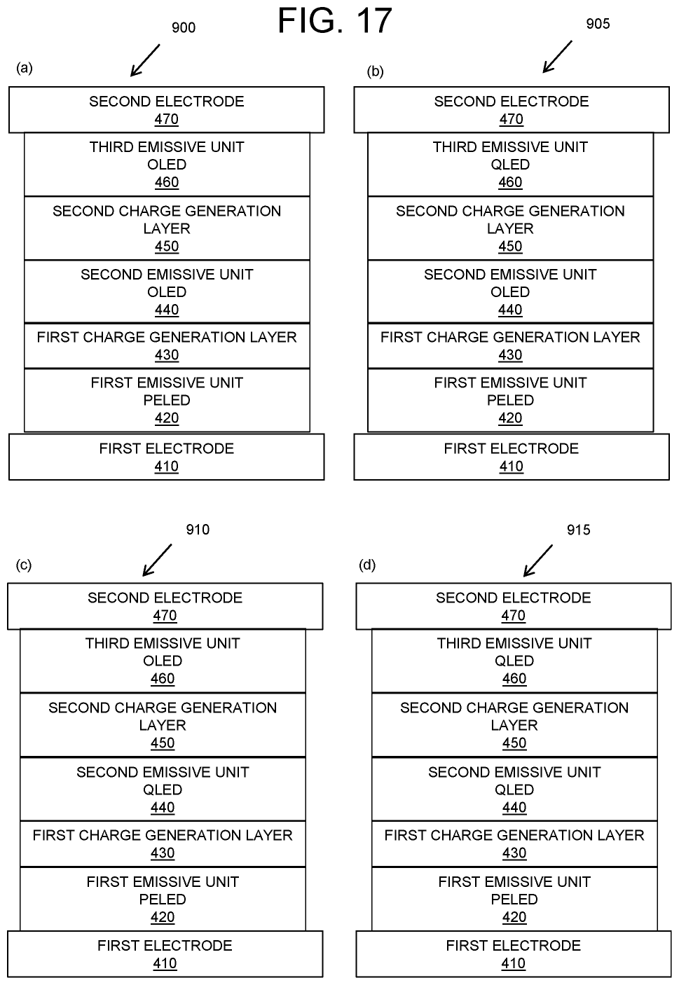

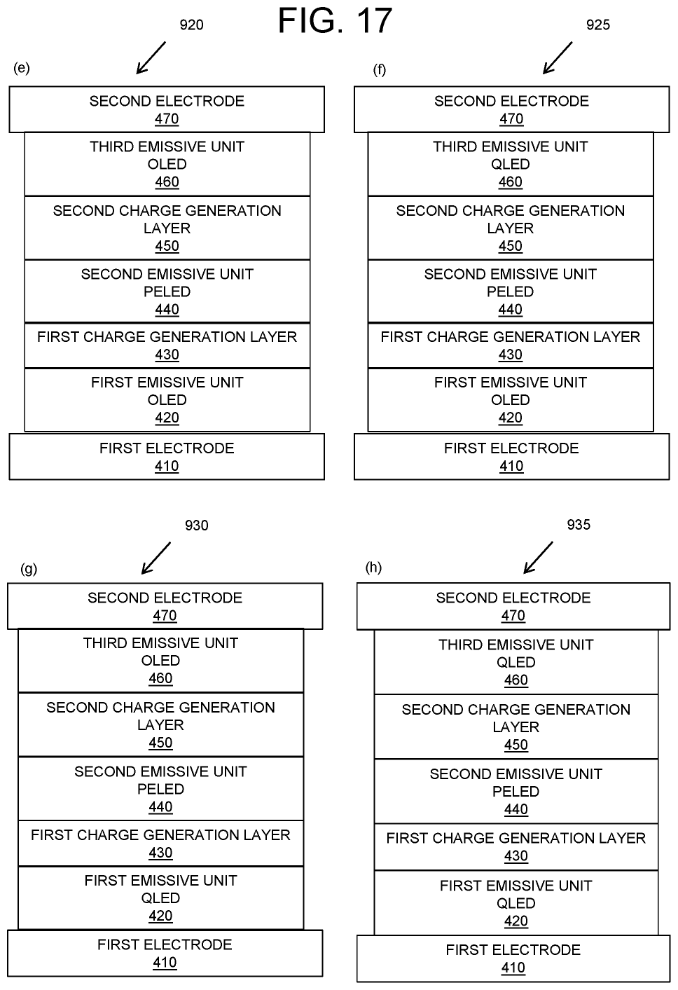

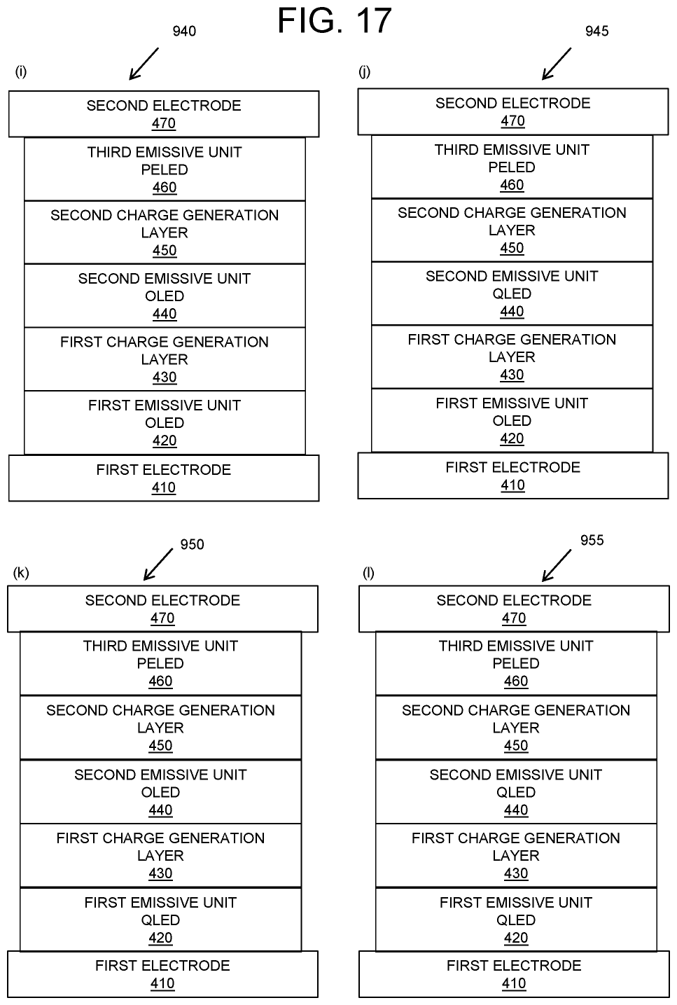

In one embodiment, the at least two further emissive units of the at least three emissive units may each comprise a perovskite light emitting material or an organic light emitting material. This embodiment is depicted by stacked light emitting devices 815 in FIG. 16d, 820 in FIG. 16e, 830 in FIG. 16g, 840 in FIG. 16i, 900 in FIG. 17a, 920 in FIGS. 17e and 940 in FIG. 17i.

In one embodiment, the first emissive unit 420 may comprise a perovskite light emitting material, the second emissive unit 440 may comprise a perovskite light emitting material, and the third emissive unit 460 may comprise a perovskite light emitting material. This embodiment is depicted by stacked light emitting device 815 in FIG. 16d. Such a device architecture may be advantageous in that the manufacturing process may be simplified for a stacked light emitting device comprising only PeLED emissive units.

In one embodiment, the at least two further emissive units of the at least three emissive units each comprise a perovskite light emitting material or an organic light emitting material, wherein at least one of the at least two further emissive units comprises an organic light emitting material. This embodiment is depicted by stacked light emitting devices 820 in FIG. 16e, 830 in FIG. 16g, 840 in FIG. 16i, 900 in FIG. 17a, 920 in FIGS. 17e and 940 in FIG. 17i. Such device architectures may be advantageous because a perovskite light emitting material may be preferred for at least one emissive unit of a stacked light emitting device, but the performance of the device may be enhanced if an organic light emitting material is used for at least one further emissive unit of the device. For example, the colour gamut, electroluminescence efficiency and/or electroluminescence stability of the device may be enhanced. Combination of PeLED emissive units with OLED emissive units within a stacked light emitting device may be particularly advantageous because organic light emitting materials with commercial performance may be complemented and enhanced by perovskite light emitting material performance.

In one embodiment, the at least two further emissive units of the at least three emissive units each comprise a perovskite light emitting material or a quantum dot light emitting material. This embodiment is depicted by exemplary stacked light emitting devices 815 in FIG. 16d, 825 in FIG. 16f, 835 in FIG. 16h, 845 in FIG. 16j, 915 in FIG. 17d, 935 in FIGS. 17h and 955 in FIG. 17l.

In one embodiment, the first emissive unit 420 may comprise a perovskite light emitting material, the second emissive unit 440 may comprise a perovskite light emitting material, and the third emissive unit 460 may comprise a perovskite light emitting material. This embodiment is depicted by stacked light emitting device 815 in FIG. 16d. Such a device architecture may be advantageous in that the manufacturing process may be simplified for a stacked light emitting device comprising only PeLED emissive units.

In one embodiment, the at least two further emissive units of the at least three emissive units each comprise a perovskite light emitting material or a quantum dot light emitting material, wherein at least one of the at least two further emissive units comprises quantum dot light emitting material. This embodiment is depicted by exemplary stacked light emitting devices 825 in FIG. 16f, 835 in FIG. 16h, 845 in FIG. 16j, 915 in FIG. 17d, 935 in FIGS. 17h and 955 in FIG. 17l. Such device architectures may be advantageous because a perovskite light emitting material may be preferred for at least one emissive unit of a stacked light emitting device, but the performance of the device may be enhanced if a quantum dot light emitting material is used for at least one further emissive unit of the device. For example, the colour gamut, electroluminescence efficiency and/or electroluminescence stability of the device may be enhanced. Combination of PeLED emissive units with QLED emissive units within a stacked light emitting device may be particularly advantageous because the similarity of structure of perovskite light-emitting materials and quantum dot light-emitting materials may allow these emissive units to be manufactured together with little or no added complexity. For example, in the case of solution-process manufacturing, common solvents may be used to process perovskite light-emitting materials and quantum dot light-emitting materials.

In one embodiment, the first emissive unit 420 may comprise a perovskite light emitting material, the second emissive unit 440 may comprise a perovskite light emitting material, and the third emissive unit 460 may comprise an organic light emitting material. This embodiment is depicted by stacked light emitting device 820 in FIG. 16e.

In one embodiment, the first emissive unit 420 may comprise a perovskite light emitting material, the second emissive unit 440 may comprise a perovskite light emitting material, and the third emissive unit 460 may comprise a quantum dot light emitting material. This embodiment is depicted by stacked light emitting device 825 in FIG. 16f.

In one embodiment, the first emissive unit 420 may comprise a perovskite light emitting material, the second emissive unit 440 may comprise an organic light emitting material, and the third emissive unit 460 may comprise a perovskite light emitting material. This embodiment is depicted by stacked light emitting device 830 in FIG. 16g.

In one embodiment, the first emissive unit 420 may comprise a perovskite light emitting material, the second emissive unit 440 may comprise a quantum dot light emitting material, and the third emissive unit 460 may comprise a perovskite light emitting material. This embodiment is depicted by stacked light emitting device 835 in FIG. 16h.

In one embodiment, the first emissive unit 420 may comprise an organic light emitting material, the second emissive unit 440 may comprise a perovskite light emitting material, and the third emissive unit 460 may comprise a perovskite light emitting material. This embodiment is depicted by stacked light emitting device 840 in FIG. 16i.

In one embodiment, the first emissive unit 420 may comprise a quantum dot light emitting material, the second emissive unit 440 may comprise a perovskite light emitting material, and the third emissive unit 460 may comprise a perovskite light emitting material. This embodiment is depicted by stacked light emitting device 845 in FIG. 16j.

FIG. 17 depicts various further configurations of emissive units for a stacked light emitting device having three emissive units. In each configuration, the stacked light emitting device comprises a first electrode 410, a first emissive unit 420, a first charge generation layer 430, a second emissive unit 440, a second charge generation layer 450, a third emissive unit 460 and a second electrode 470. The first emissive unit 420, the first charge generation layer 430, the second emissive unit 440, the second charge generation layer 450 and the third emissive unit 460 are disposed between the first electrode 410 and the second electrode 470. The first emissive unit 420 is disposed over the first electrode 410. The first charge generation layer 430 is disposed over the first emissive unit 420. The second emissive unit 440 is disposed over the first charge generation layer 430. The second charge generation layer 450 is disposed over the second emissive unit 440. The third emissive unit 460 is disposed over the second charge generation layer 450. The second electrode 470 is disposed over the third emissive unit 460. In each configuration, the stacked light emitting device comprises at least one emissive unit that comprises perovskite light emitting material.

In one embodiment, the first emissive unit 420 may comprise a perovskite light emitting material, the second emissive unit 440 may comprise an organic light emitting material, and the third emissive unit 460 may comprise an organic light emitting material. This embodiment is depicted by stacked light emitting device 900 in FIG. 17a.

In one embodiment, the first emissive unit 420 may comprise a perovskite light emitting material, the second emissive unit 440 may comprise an organic light emitting material, and the third emissive unit 460 may comprise a quantum dot light emitting material. This embodiment is depicted by stacked light emitting device 905 in FIG. 17b.

In one embodiment, the first emissive unit 420 may comprise a perovskite light emitting material, the second emissive unit 440 may comprise a quantum dot light emitting material, and the third emissive unit 460 may comprise an organic light emitting material. This embodiment is depicted by stacked light emitting device 910 in FIG. 17c.

In one embodiment, the first emissive unit 420 may comprise a perovskite light emitting material, the second emissive unit 440 may comprise a quantum dot light emitting material, and the third emissive unit 460 may comprise a quantum dot light emitting material. This embodiment is depicted by stacked light emitting device 915 in FIG. 17d.

In one embodiment, the first emissive unit 420 may comprise an organic light emitting material, the second emissive unit 440 may comprise a perovskite light emitting material, and the third emissive unit 460 may comprise an organic light emitting material. This embodiment is depicted by stacked light emitting device 920 in FIG. 17e.

In one embodiment, the first emissive unit 420 may comprise an organic light emitting material, the second emissive unit 440 may comprise a perovskite light emitting material, and the third emissive unit 460 may comprise a quantum dot light emitting material. This embodiment is depicted by stacked light emitting device 925 in FIG. 17f.

In one embodiment, the first emissive unit 420 may comprise a quantum dot light emitting material, the second emissive unit 440 may comprise a perovskite light emitting material, and the third emissive unit 460 may comprise an organic light emitting material. This embodiment is depicted by stacked light emitting device 930 in FIG. 17g.

In one embodiment, the first emissive unit 420 may comprise a quantum dot light emitting material, the second emissive unit 440 may comprise a perovskite light emitting material, and the third emissive unit 460 may comprise a quantum dot light emitting material. This embodiment is depicted by stacked light emitting device 935 in FIG. 17h.

In one embodiment the first emissive unit 420 may comprise an organic light emitting material, the second emissive unit 440 may comprise an organic light emitting material, and the third emissive unit 460 may comprise a perovskite light emitting material. This embodiment is depicted by stacked light emitting device 940 in FIG. 17i.

In one embodiment, the first emissive unit 420 may comprise an organic light emitting material, the second emissive unit 440 may comprise a quantum dot light emitting material, and the third emissive unit 460 may comprise a perovskite light emitting material. This embodiment is depicted by stacked light emitting device 945 in FIG. 17j.

In one embodiment, the first emissive unit 420 may comprise a quantum dot light emitting material, the second emissive unit 440 may comprise an organic light emitting material, and the third emissive unit 460 may comprise a perovskite light emitting material. This embodiment is depicted by stacked light emitting device 950 in FIG. 17k.

In one embodiment, the first emissive unit 420 may comprise a quantum dot light emitting material, the second emissive unit 440 may comprise a quantum dot light emitting material, and the third emissive unit 460 may comprise a perovskite light emitting material. This embodiment is depicted by stacked light emitting device 955 in FIG. 17l.

In one embodiment, at least one emissive unit of the at least two further emissive units comprises an organic light emitting material, and at least one emissive unit of the at least two further emissive units comprises a quantum dot light emitting material. This embodiment is depicted by stacked light emitting devices 905 in FIG. 17b, 910 in FIG. 17c, 925 in FIG. 17f, 930 in FIG. 17g, 945 in FIGS. 17j and 950 in FIG. 17k. Such stacked light emitting device architectures may be advantageous because the combination of different light emitting materials may enable the optimum type of light emitting material to be selected for each emissive unit, thereby enhancing performance beyond that which could be achieved by a stacked light emitting device comprising only a single type of light emitting material, or only two types of light emitting material. For example, the colour gamut, electroluminescence efficiency and/or electroluminescence stability of the device may be enhanced.

A person skilled in the art will understand that only a few examples of use are described, but that they are in no way limiting.

Modifications to embodiments of the invention described in the foregoing are possible without departing from the scope of the invention as defined by the accompanying claims. Expressions such as “including”, “comprising”, “incorporating”, “consisting of”, “have”, “is” used to describe and claim the present invention are intended to be construed in a non-exclusive manner, namely allowing for items, components or elements not explicitly described also to be present. Reference to the singular is also to be construed to relate to the plural. Any numerals included within parentheses in the accompanying claims are intended to assist understanding of the claims and should not be construed in any way to limit subject matter claimed by these claims.

### PATENT REFERENCES

EP 0423283 B1, Friend et al., Electroluminescent Devices
U.S. Pat. No. 6,303,238 B1, Thompson et al., OLEDs Doped with Phosphorescent Compounds
U.S. Pat. No. 7,279,704 B2, Walters et al., Complexes with Tridentate Ligands
U.S. Pat. No. 5,707,745 B1, Forrest et al., Multicolor Organic Light Emitting Devices

### OTHER REFERENCES

S. Adjokatse et al., Broadly tunable metal halide perovskites for solid-state light-emission applications, Materials Today, Volume 20, Issue 8, Pages 413-424 (2017).
Uoyama et al., Highly efficient organic light-emitting diodes from delayed fluorescence, Nature, Volume 492, Pages 234-238 (2012).
Kathirgamanathan et al. (1), Electroluminescent Organic and Quantum Dot LEDs: The State of the Art, Journal of Display Technology, Volume 11, Number 5, Pages 480-493 (2015).
Forrest et al., The stacked OLED (SOLED): a new type of organic device for achieving high-resolution full-color displays, Synthetic Metals, Volume 91, Issues 1-3, Pages 9-13 (1997).
Jung et al., 3 Stacked Top Emitting White OLED for High Resolution OLED TV, SID Symposium Digest of Technical Papers 2016, Volume 47, Pages 707-710 (2016).
Soneira et al., iPhone X OLED Display Technology Shoot-Out, DisplayMate Technologies Corporation, http://www.displaymate.com/iPhoneX_ShootOut_1a.htm [accessed 20 May 2018].
Wang et al., Perovskite light-emitting diodes based on solution-processed, self-organised multiple quantum wells, Nature Photonics, Volume 10, Pages 699-704 (2016).
Kathirgamanathan et al. (2), Quantum Dot Electroluminescence: Towards Achieving the REC 2020 Colour Co-ordinates, SID Symposium Digest of Technical Papers 2015, Volume 47, Pages 652-656 (2016).
Hirose et al., High-efficiency Perovskite QLED Achieving BT.2020 Green Chromaticity, SID Symposium Digest of Technical Papers 2017, Volume 48, Pages 284-287 (2017).
Kumar et al., Efficient Blue Electroluminescence Using Quantum-Confined Two-Dimensional Perovskites, ACS Nano, Volume 10, Pages 9720-9729 (2016).
Takita et al., Highly efficient deep-blue fluorescent dopant for achieving low-power OLED display satisfying BT.2020 chromaticity, Journal of the SID 2018 (2018).

1. A light emitting device comprising:
a first electrode;
a second electrode;
at least two emissive units and at least one charge generation layer;
wherein the least two emissive units and the at least one charge generation layer are disposed between the first electrode and the second electrode;
wherein a first emissive unit of the at least two emissive units is disposed over the first electrode;
wherein a first charge generation layer of the at least one charge generation layer is disposed over the first emissive unit;
wherein a second emissive unit of the at least two emissive units is disposed over the first charge generation layer;
wherein the second electrode is disposed over the second emissive unit;
wherein at least one emissive unit of the at least two emissive units comprises a perovskite light emitting material;
wherein the device comprises at least one further emissive unit of the at least two emissive units; and
wherein the at least one further emissive unit comprises a perovskite light emitting material, an organic light emitting material or a quantum dot light emitting material.

2. The device of claim 1, wherein the first emissive unit comprises a perovskite light emitting material, and the second emissive unit comprises a perovskite light emitting material, an organic light emitting material or a quantum dot light emitting material.

3. The device of claim 1, wherein the first emissive unit comprises a perovskite light emitting material, an organic light emitting material or a quantum dot light emitting material, and the second emissive unit comprises a perovskite light emitting material.

4. The device of any one of claims 1 to 3, wherein the at least one further emissive unit of the at least two emissive units comprises a perovskite light emitting material or an organic light emitting material.

5. The device of claim 4, wherein the first emissive unit comprises a perovskite light emitting material, and the second emissive unit comprises a perovskite light emitting material.

6. The device of claim 4, wherein the at least one further emissive unit of the at least two emissive units comprises an organic light emitting material.

7. The device of claim 6, wherein the first emissive unit comprises a perovskite light emitting material, and the second emissive unit comprises an organic light emitting material.

8. The device of claim 6, wherein the first emissive unit comprises an organic light emitting material, and the second emissive unit comprises a perovskite light emitting material.

9. The device of any one of claims 1 to 3, wherein the at least one further emissive unit of the at least two emissive units comprises a perovskite light emitting material or a quantum dot light emitting material.

10. The device of claim 9, wherein the first emissive unit comprises a perovskite light emitting material, and the second emissive unit comprises a perovskite light emitting material.

11. The device of claim 9, wherein the at least one further emissive unit of the at least two emissive units comprises a quantum dot light emitting material.

12. The device of claim 11, wherein the first emissive unit comprises a perovskite light emitting material, and the second emissive unit comprises a quantum dot light emitting material.

13. The device of claim 1, wherein the first emissive unit comprises a quantum dot light emitting material, and the second emissive unit comprises a perovskite light emitting material.

14. The device of any one of claims 1 to 13, wherein each emissive unit comprises one, and not more than one, emissive layer.

15. The device of any one of claims 1 to 13, wherein each emissive unit comprises one, and not more than one, light emitting material.

16. The device of any one of the preceding claims, wherein the device includes a microcavity structure.

17. The device of any one of the preceding claims, wherein the device emits red light.

18. The device of claim 17, wherein the device emits red light with CIE 1931×coordinate greater than or equal to 0.680.

19. The device of claim 17, wherein the device emits red light with CIE 1931×coordinate greater than or equal to 0.708.

20. The device of any one of the preceding claims, wherein the device emits green light.

21. The device of claim 20, wherein the device emits green light with CIE 1931 y coordinate greater than or equal to 0.690.

22. The device of claim 20, wherein the device emits green light with CIE 1931 y coordinate greater than or equal to 0.797.

23. The device of any one of the preceding claims, wherein the device emits blue light.

24. The device of claim 23, wherein the device emits blue light with CIE y coordinate less than or equal to 0.060.

25. The device of claim 23, wherein the device emits blue light with CIE y coordinate less than or equal to 0.046.

26. The device of any one of the preceding claims, wherein the device emits white light.

27. The device of any one of the preceding claims, wherein one or more of the emissive units comprise organic metal halide light-emitting perovskite material.

28. The device of any one of the preceding claims, wherein one or more of the emissive units comprise inorganic metal halide light-emitting perovskite material.

29. The device of any one of claims 1 to 28, wherein the first charge generation layer is directly connected to an external electrical source.

30. The device of claim 29, wherein the first charge generation layer is independently addressable.

31. The device of any one of claims 1 to 28, wherein the first charge generation layer is not directly connected to an external electrical source.

32. The device of claim 31, wherein the first charge generation is not independently addressable.

33. The device of any one of claims 1 to 28, wherein the first emissive unit and the second emissive unit are electrically connected in series.

34. The device of any one of claims 1 to 28, wherein direct current passes through the first emissive unit and the second emissive unit.

35. A sub-pixel of a display comprising the device of any one of the preceding claims.

36. A light panel comprising the device of any one of the preceding claims.

37. A light emitting device comprising:
a first electrode;
a second electrode;
at least three emissive units and at least two charge generation layers;
wherein the at least three emissive units and the at least two charge generation layers are disposed between the first electrode and the second electrode;
wherein a first emissive unit of the at least three emissive units is disposed over the first electrode;
wherein a first charge generation layer of the at least two charge generation layers is disposed over the first emissive unit;
wherein a second emissive unit of the at least three emissive units is disposed over the first charge generation layer;
wherein a second charge generation layer of the at least two charge generation layers is disposed over the second emissive unit;
wherein a third emissive unit of the at least three emissive units is disposed over the second charge generation layer;
wherein the second electrode is disposed over the third emissive unit;
wherein at least one emissive unit of the at least three emissive units comprises a perovskite light emitting material;
wherein the device comprises at least two further emissive units of the at least three emissive units; and
wherein each of the at least two further emissive units comprises a perovskite light emitting material, an organic light emitting material or a quantum dot light emitting material.

38. The device of claim 37, wherein the at least two further emissive units of the at least three emissive units each comprise a perovskite light emitting material or an organic light emitting material.

39. The device of claim 37 or claim 38, wherein the first emissive unit comprises a perovskite light emitting material, the second emissive unit comprises a perovskite light emitting material, and the third emissive unit comprises a perovskite light emitting material.

40. The device of any one of claims 37 to 39, wherein at least one emissive unit of the at least two further emissive units comprises an organic light emitting material.

41. The device of claim 37, wherein the at least two further emissive units of the at least three emissive units each comprise a perovskite light emitting material or a quantum dot light emitting material.

42. The device of claim 41, wherein the first emissive unit comprises a perovskite light emitting material, the second emissive unit comprises a perovskite light emitting material, and the third emissive unit comprises a perovskite light emitting material.

43. The device of claim 41 or claim 42, wherein at least one emissive unit of the at least two further emissive units comprises a quantum dot light emitting material.

44. The device of claim 37, wherein at least one emissive unit of the at least two further emissive units comprises an organic light emitting material, and at least one emissive unit of the at least two further emissive units comprises a quantum dot light emitting material.

45. A sub-pixel of a display comprising the device of any one of claims 37 to 44.

46. A light panel comprising the device of any one of claims 37 to 44.
